(19) United States
(12) Patent Application Publication
(10) Pub. No.: US 2026/0177809 A1
(43) Pub. Date: Jun. 25, 2026

(54) SPATIAL LIGHT MODULATION UNIT AND EXPOSURE DEVICE

(71) Applicant: NIKON CORPORATION, Tokyo (JP)

(72) Inventors: Kensuke TOKUMI, Tokyo (JP); Satoshi KAWADO, Tokyo (JP); Hiroshi KAJIYAMA, Yokohama-shi (JP); Yusuke MATSUHASHI, Yokohama-shi (JP); Koki YAMAGUCHI, Fujisawa-shi (JP); Yuu HASEGAWA, Tokyo (JP)

(73) Assignee: NIKON CORPORATION, Tokyo (JP)

(21) Appl. No.: 19/422,982

(22) Filed: Dec. 17, 2025

Related U.S. Application Data
(63) Continuation of application No. PCT/JP2023/023359, filed on Jun. 23, 2023.

(51) Int. Cl. G02B 26/08; G03F 7/00

(52) U.S. Cl. CPC G02B 26/0833; G02B 26/0841; G03F 7/70291

(57) ABSTRACT

A spatial light modulation unit includes a spatial light modulator including a substrate, a plurality of mirrors arranged on a surface of the substrate in a plan view, and a frame body that is located over the substrate and surrounds the plurality of mirrors in the plan view, and a cover that is located over the frame body, is attached to the spatial light modulator so that a relative positional relationship with the spatial light modulator is fixed, and restricts incidence of light on the frame body, wherein a first surface of the cover faces the frame body, an opening of the cover extends from a side of the first surface to a side of a second surface, which is opposite to the side of the first surface, of the cover, and each of the plurality of mirrors is able to be brought into a plurality of states.

### CROSS-REFERENCE TO RELATED APPLICATION

This application is a continuation application of the prior International Patent Application No. PCT/JP2023/023359, filed on Jun. 23, 2023, the entire contents of which are incorporated herein by reference.

### FIELD

The present disclosure relates to a spatial light modulation unit and an exposure device.

### BACKGROUND

In the lithography process for manufacturing electronic devices (microdevices) such as display panels using liquid crystal or organic EL, semiconductor elements (integrated circuits, etc.), etc., a step-and-repeat projection exposure device (so-called stepper), a step-and-scan projection exposure device (so-called scanning stepper (also called scanner)), etc., have traditionally been used. This type of exposure device projects and exposes a mask pattern for an electronic device onto a photosensitive layer applied on the surface of a substrate to be exposed (hereinafter, also simply referred to as a substrate) such as a glass substrate, a semiconductor wafer, a printed wiring board, or a resin film.

Since it takes time and cost to fabricate a mask substrate on which the mask pattern is fixedly formed, an exposure device using a spatial light modulator (variable mask pattern generator) such as a digital mirror device (DMD) in which a large number of micromirrors that are slightly displaced are regularly arranged instead of the mask substrate is known as disclosed in, for example, Japanese Patent Application Publication No. 2019-23748. In the exposure device disclosed in PTL 1, for example, illumination light obtained by mixing light from a laser diode (LD) of 375 nm wavelength and light from an LD of 405 nm wavelength with a multimode fiber bundle is irradiated to a digital mirror device (DMD), and reflected light from each of a large number of micromirrors whose inclinations are controlled is projected and exposed onto a substrate through an imaging optical system and a microlens array.

### SUMMARY

In the exposure device, it is desired to inhibit the generation of stray light.

According to a first aspect of the present disclosure, there is provided a spatial light modulation unit including: a spatial light modulator including a substrate, a plurality of mirrors arranged on a surface of the substrate in a plan view, and a frame body that is located over the substrate and surrounds the plurality of mirrors in the plan view; and a cover that is located over the frame body, is attached to the spatial light modulator so that a relative positional relationship with the spatial light modulator is fixed, and restricts incidence of light on the frame body, wherein a first surface of the cover faces the frame body, an opening of the cover extends from a side of the first surface to a side of a second surface, which is opposite to the side of the first surface, of the cover, and each of the plurality of mirrors is able to be brought into a plurality of states.

According to a second aspect of the present disclosure, there is provided an exposure device including: the above spatial light modulation unit; and a projection unit that projects light from the spatial light modulator onto an object, wherein tan θin<Lin/Hin is satisfied, light from a mirror in an ON state of the plurality of mirrors enters the projection unit, θin is twice an inclination angle of a reflection surface of the mirror in the ON state of the plurality of mirrors from a plane including respective centers of the plurality of mirrors, Lin is a distance between an edge of the opening and a mirror closest to the edge among the plurality of mirrors in the plan view, and Hin is a distance between a plane that includes respective points closest to the substrate in respective reflection surfaces of mirrors in the ON state of the plurality of mirrors and the first surface.

According to a third aspect of the present disclosure, there is provided an exposure device including: the above spatial light modulation unit; and a projection unit that projects light from the spatial light modulator onto an object, wherein a distance between a plane including respective centers of the plurality of mirrors and the first plane is H, a distance between an edge of the opening and a mirror closest to the edge of the opening among the plurality of mirrors in a plan view is L, a numerical aperture of the projection unit is NA, a refractive index on an optical path from the spatial light modulator to the projection unit is n, and an optical magnification is β, and tan θ_{NA}<L/H is satisfied, where θ_{NA}=sin⁻¹(NA×β/n).

According to a fourth aspect of the present disclosure, there is provided an exposure device including: a spatial light modulator including a modulation unit having a plurality of elements arranged two dimensionally and a frame body that accommodates the modulation unit; an illumination unit that illuminates the spatial light modulator with illumination light; a projection unit that projects light from the spatial light modulator onto an object to be scanned in a scanning direction; and a light-shielding cover that blocks light reflected by the frame body of the illumination light from traveling to the object.

According to a fifth aspect of the present disclosure, there is provided an exposure device including: a spatial light modulator including a plurality of elements arranged on a surface in a plan view and a frame body surrounding the plurality of elements in the plan view; an illumination unit that illuminates the spatial light modulator with illumination light; a light shielding portion that is attached to the spatial light modulator so that a relative positional relationship with the spatial light modulator is fixed and blocks the illumination light from entering the frame body; a projection unit that projects light from the plurality of elements onto an object; and a stage on which the spatial light modulator is mounted and that is movable in a plane intersecting an optical axis of the projection unit, wherein an illumination region of the illumination unit is set so that the plurality of elements and a region surrounding the plurality of elements in the plan view are illuminated with the illumination light, the plurality of elements are irradiated by the illumination region regardless of a position of the stage within a movable range in a first direction in the plane of the stage, and the plurality of elements are irradiated by the illumination region regardless of a position of the stage within a movable range in a second direction, which intersects with the first direction in the plane, of the stage.

The configuration of the embodiments described later may be appropriately improved, and at least a part thereof may be replaced with other components. Furthermore, the constituent elements whose arrangement is not particularly limited are not limited to the arrangement disclosed in the embodiment, and can be arranged at positions where the functions thereof can be achieved.

### BRIEF DESCRIPTION OF THE DRAWINGS

FIG. 1 is a perspective view illustrating an overview of an external configuration of an exposure device according to a first embodiment;

FIG. 2 illustrates an example of arrangement of projection areas of DMDs projected onto a substrate by respective projection units of a plurality of exposure modules;

FIG. 3 is a diagram for describing a state of stitching exposure by each of four specific projection areas in FIG. 2;

FIG. 4 is an optical arrangement diagram illustrating a specific configuration of two exposure modules arranged in the X-axis direction (scanning exposure direction) as viewed in the XZ plane;

FIG. 5A schematically illustrates a DMD, FIG. 5B illustrates the DMD when the power supply is OFF, FIG. 5C is a view for describing a mirror in an ON state, and FIG. 5D is a view for describing a mirror in an OFF state;

FIG. 6A is a perspective view illustrating a DMD chip including a DMD, and FIG. 6B is a diagram illustrating an X′Z′ cross-section of the DMD chip;

FIG. 7A illustrates a mount portion to which the DMD chip is attached as viewed from the −Z direction, and FIG. 7B illustrates the mount portion to which a light-shielding cover is attached;

FIG. 8A is a cross-sectional view for describing the arrangement of the DMD chip and the light-shielding cover, FIG. 8B is a cross-sectional view for describing the size of the opening of the DMD chip and the positional relationship between the DMD chip and the opening, and FIG. 8C and FIG. 8D are views of the DMD and the opening as viewed from the −Z direction;

FIG. 9 is a diagram for describing a relationship between arrangement of the opening and the DMD and discarded light;

FIG. 10 schematically illustrates a state in which the DMD and an illumination unit are inclined by an angle θk in the XY plane;

FIG. 11 is a view illustrating another example of the opening of the light-shielding cover;

FIG. 12 is a diagram for describing the light-shielding cover that prevents scattered light from traveling;

FIG. 13 is an optical arrangement diagram of a specific configuration of the exposure module in a second embodiment as viewed in the XZ plane;

FIG. 14 is a diagram for describing in detail an image forming state of the micromirrors of the DMD by the projection unit;

FIG. 15A is a diagram schematically illustrating a projection area (light irradiation area group) and an exposure target area (area where a line pattern is exposed) on a substrate, and FIG. 15B is a diagram illustrating an arrangement example of spot positions in the exposure target area;

FIG. 16A is a plan view of a field stop FS, and FIG. 16B is a cross-sectional view taken along line A-A in FIG. 16A;

FIG. 17A is a diagram for describing the arrangement of the field stop, and FIG. 17B is a diagram illustrating an illuminance distribution of illumination light formed by the field stop;

FIG. 18A is a diagram illustrating an example of an illuminance distribution of illumination light, and FIG. 18B illustrates an example in which a rectangular area is exposed with illumination light having the illuminance distribution illustrated in FIG. 18A;

FIG. 19A is a diagram illustrating how a rectangular area is exposed, and FIG. 19B is a diagram illustrating how the rectangular area is exposed when integrated illuminance is corrected;

FIG. 20 is a diagram illustrating micromirrors to be set to the OFF state in the DMD;

FIG. 21 illustrates the substrate holder as viewed from the +Z direction;

FIG. 22 is a functional block diagram illustrating a functional configuration of an exposure control device;

FIG. 23 is a flowchart illustrating an example of a process executed by a drawing data creation unit;

FIG. 24A is a diagram for describing another example of the arrangement of the field stop, and FIG. 24B is a diagram illustrating another example of the illuminance distribution of the illumination light formed by the field stop;

FIG. 25A is a plan view illustrating an example of a field stop having an opening, FIG. 25B is a side view of the field stop, FIG. 25C is a cross-sectional view taken along line A-A in FIG. 25A, FIG. 25D is a cross-sectional view taken along line B-B in FIG. 25B, and FIG. 25E is a cross-sectional view taken along line C-C in FIG. 25B;

FIG. 26A illustrates a light-shielding cover according to a first variation, and FIG. 26B illustrates a light-shielding cover according to a second variation;

FIG. 27 illustrates a field stop according to a third variation;

FIG. 28 is a diagram illustrating a third embodiment in which a pattern glass is arranged;

FIG. 29A and FIG. 29B are diagrams illustrating other examples of the light shielding pattern;

FIG. 30A and FIG. 30B are diagrams illustrating other examples of the light-shielding pattern; and

FIG. 31 is a diagram for describing a case where the size of the illumination field area is set smaller than the size of the DMD.

### DESCRIPTION OF EMBODIMENTS

### First Embodiment

A pattern exposure device (hereinafter, simply referred to as an exposure device) according to a first embodiment will be described with reference to the drawings.

### [Overall Configuration of the Exposure Device]

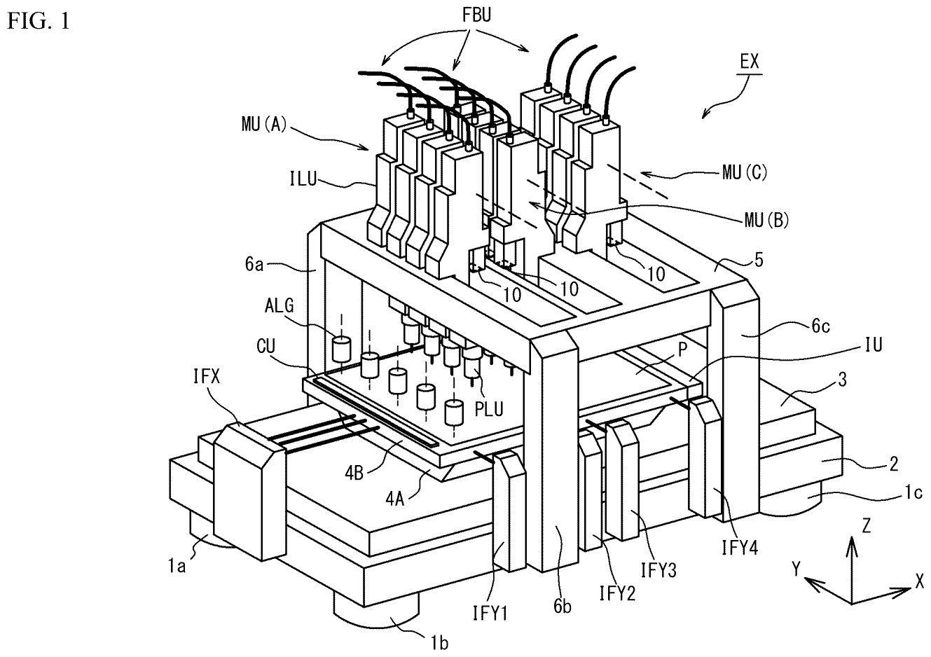

FIG. 1 is a perspective view illustrating an overview of an external configuration of an exposure device EX according to the first embodiment. The exposure device EX is a device that forms and projects an image of exposure light, whose intensity distribution in a space is dynamically modulated by a spatial light modulator (SLM), onto a substrate to be exposed. Examples of the spatial light modulator include a liquid crystal element, a digital micromirror device (DMD), and a magneto optic spatial light modulator (MOSLM). The exposure device EX according to the present embodiment includes a DMD chip including a DMD 10 as the spatial light modulator, but may include other spatial light modulators.

In a specific embodiment, the exposure device EX is a step-and-scan projection exposure device (scanner) that uses rectangular (square) glass substrates used in display device (flat panel displays) or the like as an exposure target. The glass substrate is a substrate P for a flat panel display having at least one side length or diagonal length of 500 mm or greater and a thickness of 1 mm or less. The exposure device EX exposes a projection image of a pattern formed by the DMD onto a photosensitive layer (photoresist) formed with a uniform thickness on the surface of the substrate P. The substrate P carried out from the exposure device EX after the exposure is sent to a predetermined process step (a film forming step, an etching step, a plating step, or the like) after the development step.

The exposure device EX includes a stage device including: a pedestal 2 placed on active anti-vibration units 1a, 1b, 1c, and 1d (1d is not illustrated), a surface plate 3 placed on the pedestal 2, an XY stage 4A that is two dimensionally movable on the surface plate 3, a substrate holder 4B that holds the substrate P on a plane by suction on the XY stage, and laser length measuring interferometers (hereinafter, also simply referred to as interferometers) IFX, IFY1 to IFY4 that measure the two-dimensional movement position of the substrate holder 4B (substrate P). Such a stage device is disclosed in, for example, U.S. Patent Application Publication No. 2010/0018950 and U.S. Patent Application Publication No. 2012/0057140.

In FIG. 1, the XY plane of the orthogonal coordinate system XYZ is set parallel to the flat face of the surface plate 3 of the stage device, and the XY stage 4A is set to be capable of translational movement within the XY plane. In the present embodiment, the direction parallel to the X-axis of the XYZ-coordinate system is set as the scanning movement direction of the substrate P (XY stage 4A) during scanning exposure. The movement position of the substrate P in the X-axis direction is sequentially measured by the interferometer IFX, and the movement position in the Y-axis direction is sequentially measured by at least one (preferably two or more) of the four interferometers IFY1 to IFY4. The substrate holder 4B is configured to be slightly movable in the direction of the Z-axis perpendicular to the XY plane with respect to the XY stage 4A and to be slightly tiltable in any direction with respect to the XY plane, allowing active focus adjustment and leveling (parallelism) adjustment between the surface of the substrate P and the image plane of the projected pattern. Further, the substrate holder 4B is configured to be capable of minute rotation (θz rotation) around an axis parallel to the Z-axis in order to actively adjust the tilt of the substrate P in the XY plane.

The exposure device EX further includes an optical surface plate 5 that holds a plurality of exposure (drawing) modules MU(A), MU(B), and MU(C), and main columns 6a, 6b, 6c, and 6d (6d is not illustrated) that support the optical surface plate 5 from the pedestal 2. Each of the plurality of exposure modules MU(A), MU(B), and MU(C) is attached to the +Z-direction side of the optical surface plate 5. The plurality of exposure modules MU(A), MU(B), and MU(C) may be individually attached to the optical surface plate 5, or may be attached to the optical surface plate 5 in a state in which rigidity is increased by coupling two or more exposure modules. Each of the plurality of exposure modules MU(A), MU(B), and MU(C) has an illumination unit ILU that is attached to the +Z-direction side of the optical surface plate 5 and receives illumination light from an optical fiber unit FBU, and a projection unit PLU that is attached to the −Z-direction side of the optical surface plate 5 and has an optical axis parallel to the Z-axis. Further, each of the exposure modules MU(A), MU(B), and MU(C) includes a DMD 10 as a modulation unit that reflects the illumination light from the illumination unit ILU toward the −Z direction and causes the illumination light to enter the projection unit PLU. The detailed configuration of the exposure module formed by the illumination unit ILU, the DMD 10 and the projection unit PLU will be described later.

A plurality of alignment systems (microscopes) ALG that detect alignment marks formed at a plurality of predetermined positions on the substrate P are attached to the −Z-direction side of the optical surface plate 5 of the exposure device EX. Further, a calibration reference unit CU for calibration is provided in the −X direction end on the substrate holder 4B. The calibration includes at least one of checking (calibration) of the relative positional relationship in the XY plane of the detection field of each of the alignment systems ALG, checking (calibration) of the baseline error between each projection position of the pattern image projected from each projection unit PLU of the exposure modules MU(A), MU(B), and MU(C) and the position of the detection field of each of the alignment systems ALG, and checking of the position and image quality of the pattern image projected from the projection unit PLU. Although some are not illustrated in FIG. 1, in the present embodiment, each of the exposure modules MU(A), MU(B), and MU(C) includes nine modules arranged at regular intervals in the Y-axis direction as an example, but the number of modules may be less than nine or greater than nine. In FIG. 1, the exposure modules are arranged in three columns in the X-axis direction, but the number of columns of the exposure modules arranged in the X-axis direction may be two or less, or four or more.

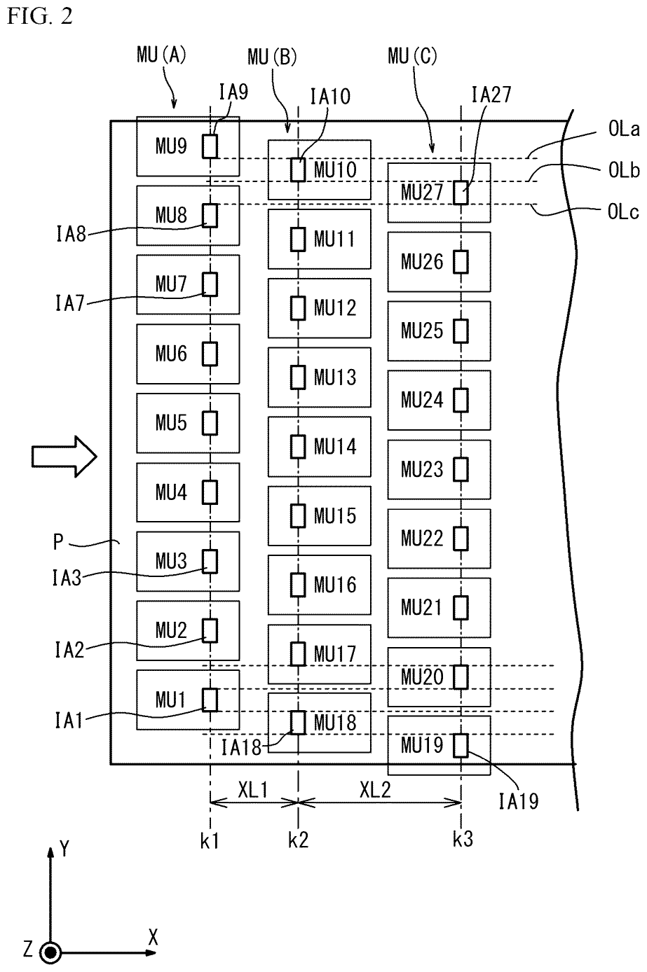

FIG. 2 illustrates an example of the arrangement of projection areas IAn of the DMDs 10 projected onto the substrate P by the projection units PLU of the exposure modules MU(A), MU(B), and MU(C) and the orthogonal coordinate system XYZ is set in the same manner as in FIG. 1. The projection area IAn can be said to be the illumination range (light irradiation area group) of the illumination light reflected by a plurality of micromirrors Ms of the DMD 10 and guided onto the substrate P by the projection unit PLU. In the present embodiment, each of the exposure module MU(A) in the first column, the exposure module MU(B) in the second column, and the exposure module MU(C) in the third column, which are arranged apart from each other in the X-axis direction, includes nine modules arranged in the Y-axis direction. The exposure module MU(A) includes nine modules MU1 to MU9 disposed in the +Y direction, the exposure module MU(B) includes nine modules MU10 to MU18 disposed in the −Y direction, and the exposure module MU(C) includes nine modules MU19 to MU27 disposed in the +Y direction. The modules MU1 to MU27 all have the same configuration, and when the exposure module MU(A) and the exposure module MU(B) are positioned facing each other in the X-axis direction, the exposure module MU (B) and the exposure module MU(C) are positioned back-to-back in the X-axis direction.

In FIG. 2, the shapes of respective projection areas IA1, IA2, IA3, . . . , IA27 (also represented as IAn where n is 1 to 27) by the modules MU1 to MU7 are, for example, rectangles extending in the Y-axis direction with an aspect ratio of approximately 1:2. In the present embodiment, with the scanning movement of the substrate P in the +X direction, the stitching exposure is performed at the end portion in the −Y direction of each of the projection areas IA1 to IA9 in the first column and the end portion in the +Y direction of each of the projection areas IA10 to IA18 in the second column. Then, the regions on the substrate P that were not exposed in each of the projection areas IA1 to IA18 in the first and second columns are subjected to the stitching exposure by the projection areas IA19 to IA27 in the third column. The center points of the projection areas IA1 to IA9 in the first column are located on a line k1 parallel to the Y-axis, the center points of the projection areas IA10 to IA18 in the second column are located on a line k2 parallel to the Y-axis, and the center points of the projection areas IA19 to IA27 in the third column are located on a line k3 parallel to the Y-axis. The interval between the line k1 and the line k2 in the X-axis direction is set to the distance XL1, and the interval between the line k2 and the line k3 in the X-axis direction is set to the distance XL2.

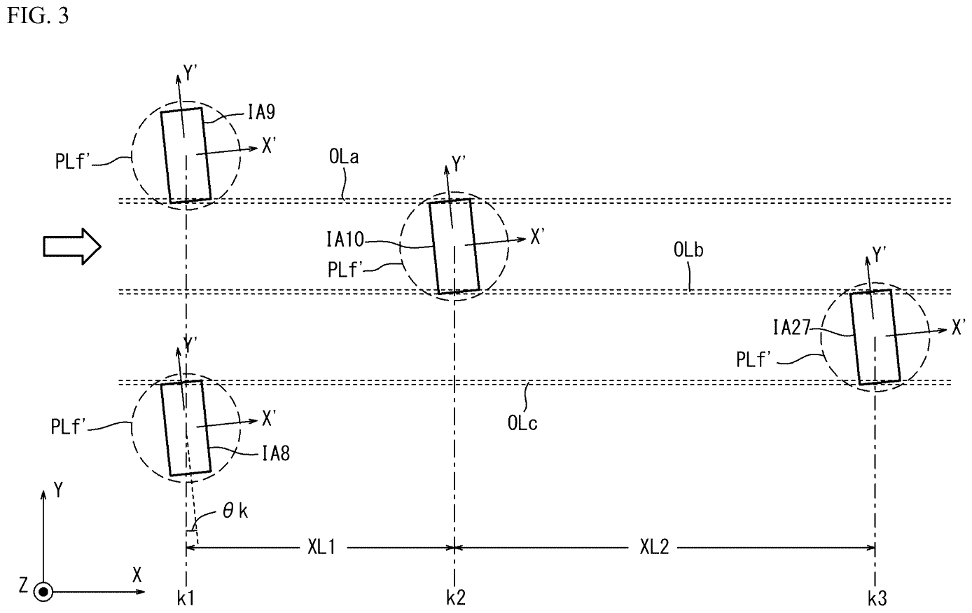

Here, when a stitched portion between the end portion of the projection area IA9 in the −Y direction and the end portion of the projection area IA10 in the +Y direction is denoted by OLa, a stitched portion between the end portion of the projection area IA10 in the −Y direction and the end portion of the projection area IA27 in the +Y direction is denoted by OLb, and a stitched portion between the end portion of the projection area IA8 in the +Y direction and the end portion of the projection area IA27 in the −Y direction is denoted by OLc, the state of the stitching exposure will be described with reference to FIG. 3. In FIG. 3, the orthogonal coordinate system XYZ is set in the same manner as in FIG. 1 and FIG. 2, and the coordinate systems X′Y′ in the projection areas IA8, IA9, IA10, and IA27 (and all other projection areas IAn) are set to be inclined by an angle θk (0°<θk<90°) with respect to the X-axis and the Y-axis (lines k1 to k3) of the orthogonal coordinate system XYZ. That is, the areas (light illumination regions) on the substrate P onto which the illumination light reflected by the large number of micromirrors of the DMD 10 is projected are two dimensionally arranged along the X′-axis and the Y′-axis.

The circular area encompassing each of the projection areas IA8, IA9, IA10, IA27 (and all other projection areas IAn as well) in FIG. 3 represents the circular image field PLf′ of the projection unit PLU. In the stitched portion OLa, the projected images (light illumination regions) of the micromirrors arranged obliquely (at the angle θk) in the end portion in the −Y′ direction of the projection area IA9 and the projected images (light illumination regions) of the micromirrors arranged obliquely (at the angle θk) in the end portion in the +Y′ direction of the projection area IA10 are set to overlap each other. In the stitched portion OLb, the projected images (light illumination regions) of the micromirrors arranged obliquely (at the angle θk) in the end portion of the −Y′ direction of the projection area IA10 and the projected images (light illumination regions) of the micromirrors arranged obliquely (at the angle θk) in the end portion in the +Y′ direction of the projection area IA27 are set so as to overlap each other. Similarly, in the stitched portion OLc, the projected images (light illumination regions) of the micromirrors arranged obliquely (at the angle θk) in the end portion in the +Y′ direction of the projection area IA8 and the projected images (light illumination regions) of the micromirrors arranged obliquely (at the angle θk) in the end portion in the −Y′ direction of the projection area IA27 are set to overlap each other.

### [Configuration of Illumination Unit]

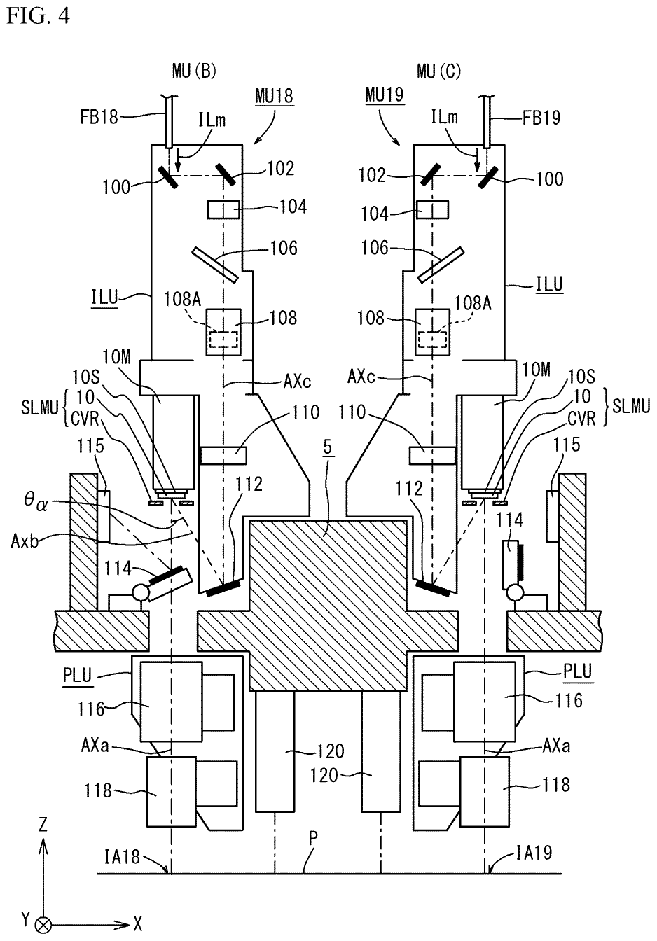

FIG. 4 is an optical arrangement diagram illustrating a specific configuration of the module MU18 in the exposure module MU(B) and the module MU19 in the exposure module MU(C) illustrated in FIG. 1 and FIG. 2, as viewed in the XZ plane. The orthogonal coordinate system XYZ in FIG. 4 is set to be the same as the orthogonal coordinate system XYZ in FIG. 1 to FIG. 3. As is clear from the arrangement of the modules in the XY plane illustrated in FIG. 2, the module MU18 is shifted by a predetermined distance in the +Y direction with respect to the module MU19, and the modules are arranged back to back. Since each optical member in the module MU18 and each optical member in the module MU19 are formed of the same material and are configured in the same manner, the optical configuration of the module MU18 will be mainly described in detail here. The optical fiber unit FBU illustrated in FIG. 1 includes 27 optical fiber bundles FB1 to FB27 corresponding to the 27 modules MU1 to MU27, respectively, illustrated in FIG. 2.

The illumination unit ILU of the module MU18 includes a mirror 100 that reflects the illumination light ILm traveling in the −Z direction from the emission end of the optical fiber bundle FB18, a mirror 102 that reflects the illumination light ILm from the mirror 100 in the −Z direction, an input lens system 104 that acts as a collimator lens, an illuminance adjustment filter 106, an optical integrator 108 including a micro fly-eye (MFE) lens, a field lens, and the like, a condenser lens system 110, and an inclined mirror 112 that reflects the illumination light ILm from the condenser lens system 110 toward the DMD 10. The mirror 102, the input lens system 104, the optical integrator 108, the condenser lens system 110, and the inclined mirror 112 are arranged along an optical axis AXc parallel to the Z-axis.

The optical fiber bundle FB18 is composed of a single optical fiber cable or multiple optical fiber cables bundled together. The illumination light ILm emitted from the emission end of the optical fiber bundle FB18 (each of the optical fiber cables) is set to have a numeric aperture (NA, also referred to as a spread angle) so as to be incident without being blocked by the input lens system 104 in the subsequent stage. Here, the illumination light ILm is light having a peak wavelength within a wavelength range of 10 nm to 410 nm, and the peak wavelength is, for example, any of 193 nm, 248 nm, 365 nm (i-line), 405 nm (h-line), and 436 nm (g-line).

The position of the front focal point of the input lens system 104 is set to be the same as the position of the emission end of the optical fiber bundle FB18. Further, the position of the rear focal point of the input lens system 104 is set so that the illumination light ILm from the single or plurality of point light sources formed at the emission end of the optical fiber bundle FB18 is superimposed at the incident surface side of the MFE lens 108A of the optical integrator 108. Therefore, the incident surface of the MFE lens 108A is Koehler-illuminated by the illumination light ILm from the emission end of the optical fiber bundle FB18. In the initial state, the geometric center point of the emission end of the optical fiber bundle FB18 in the XY plane is located on the optical axis AXc, and the main light beam (center line) of the illumination light ILm from the point source at the emission end of the optical fiber bundle is parallel to (or coaxial with) the optical axis AXc.

The illumination light ILm from the input lens system 104 is attenuated in illumination by any value within a range of 0% to 90% by the illuminance adjustment filter 106, and then passes through the optical integrator 108 (MFE lens 108A, field lens, etc.) to enter the condenser lens system 110. The MFE lens 108A is formed by two dimensionally arranging a large number of rectangular microlenses each having a size of several tens of micrometers square, and the overall shape thereof is configured to be substantially similar to the shape of the entire mirror surface of the DMD 10 (aspect ratio is approximately 1:2) in the XY plane. The position of the front focal point of the condenser lens system 110 is set to be substantially the same as the position of the emission surface of the MFE lens 108A. Therefore, the illumination light from the point light sources formed on the emission sides of the large number of microlenses of the MFE lens 108A is converted into substantially parallel light fluxes by the condenser lens system 110, reflected by the inclined mirror 112, and then superimposed on the DMD 10 to form a uniform illuminance distribution. The MFE lens 108A functions as a surface light source component because a surface light source in which a large number of point light sources (focus points) are two-dimensionally and densely arranged is generated on the emission surface of the MFE lens 108A.

In the module MU18 illustrated in FIG. 4, the optical axis AXc parallel to the Z-axis passing through the condenser lens system 110 is bent by the inclined mirror 112 and reaches the DMD 10, and an optical axis between the inclined mirror 112 and the DMD 10 is defined as an optical axis AXb. In the present embodiment, a neutral plane including the center point of each of the large number of micromirrors of the DMD 10 is set to be parallel to the XY plane. Therefore, the angle between the normal line (parallel to the Z-axis) of the neutral plane and the optical axis AXb is the incident angle θα of the illumination light ILm with respect to the DMD 10.

### [Configuration of DMD]

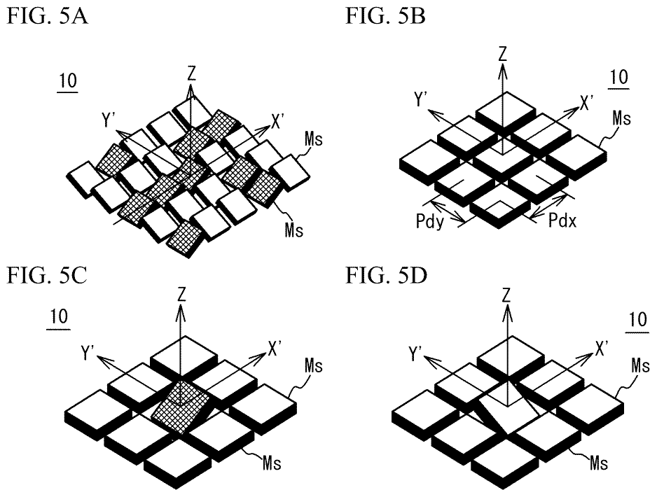

FIG. 5A schematically illustrates a DMD 10, FIG. 5B is a diagram illustrating the DMD 10 when the power is OFF, FIG. 5C is a diagram for describing a mirror in an ON state, and FIG. 5D is a diagram for describing a mirror in an OFF state. In FIG. 5A to FIG. 5D, the mirrors in the ON state are indicated by hatching.

The DMD 10 has a plurality of micromirrors Ms capable of controlling the reflection angle. In the present embodiment, the DMD 10 is of a roll and pitch driving type that switches between the ON state and the OFF state by the tilt of the micromirror Ms in the roll direction and the tilt of the micromirror Ms in the pitch direction.

As illustrated in FIG. 5B, when the power is OFF (the micromirrors Ms are in the neutral state), the reflection surface of each micromirror Ms is set parallel to the X′Y′ plane. The arrangement pitch of the micromirrors Ms in the X′-axis direction is denoted by Pdx (μm), and the arrangement pitch in the Y′-axis direction is denoted by Pdy (μm), but in practice, Pdx and Pdy is set to be equal to each other.

Each micromirror Ms enters the ON state by tilting around the Y′ axis. FIG. 5C illustrates a case where only the central micromirror Ms is in the ON state and the other micromirrors Ms are in the neutral state (neither ON nor OFF). Furthermore, each micromirror Ms enters the OFF state by tilting around the X′ axis. FIG. 5D illustrates a case where only the central micromirror Ms is in the OFF state and the other micromirrors Ms are in the neutral state. Although not illustrated for the sake of simplicity, the ON-state micromirrors Ms are driven to be inclined at a predetermined angle from the X′Y′ plane so that the illumination light irradiated onto the ON-state micromirrors Ms is reflected in the X-axis direction of the XZ plane. The OFF-state micromirror Ms is driven to be inclined at a predetermined angle from the X′Y′ plane so that the illumination light irradiated onto the OFF-state micromirror Ms is reflected in the Y-axis direction in the YZ plane. The DMD 10 generates an exposure pattern by switching the ON state and the OFF state of each micromirror Ms.

The illumination light reflected by the mirror in the OFF state is absorbed by a light absorber (not illustrated).

Since the DMD 10 is described as an example of the spatial light modulator, the spatial light modulator is described as a reflective spatial light modulator that reflects laser light, but the spatial light modulator may be of a transmissive type that transmits laser light or of a diffractive type that diffracts laser light. The spatial light modulator can spatially and temporally modulate the laser light.

Referring back to FIG. 4, the illumination light ILm irradiated onto the micromirror Ms in the ON state among the micromirrors Ms of the DMD 10 is reflected in the X-axis direction in the XZ plane so as to be directed to the projection unit PLU. On the other hand, the illumination light ILm irradiated onto the micromirror Ms in the OFF state of the micromirrors Ms of the DMD 10 is reflected in the Y-axis direction in the YZ plane so as not to be directed to the projection unit PLU.

A movable shutter 114 for shielding the reflected light from the DMD10 during the non-exposure period is provided in the optical path between the DMD 10 and the projection unit PLU so as to be inserted and removed. The movable shutter 114 is rotated to an angular position where it is retracted from the optical path during the exposure period as illustrated on the module MU19 side, and is rotated to an angular position where it is obliquely inserted into the optical path during the non-exposure period as illustrated on the module MU18 side. A reflection surface is formed on the DMD 10 side of the movable shutter 114, and the light from the DMD 10 reflected by the reflection surface is irradiated onto the light absorber 115. The light absorber 115 absorbs optical energy in the ultraviolet wave range (wavelength of 400 nm or less) without re-reflecting it and converts it into thermal energy. Therefore, the light absorber 115 is also provided with a heat dissipation mechanism (a heat dissipation fin or a cooling mechanism). Although not illustrated in FIG. 4, the reflected light from the micromirrors Ms in the OFF state of the DMD 10 during the exposure period is absorbed by a similar light absorber (not illustrated in FIG. 4) disposed in the Y-axis direction (the direction perpendicular to the plane of FIG. 4) with respect to the optical path between the DMD 10 and the projection unit PLU, as described above.

### [DMD Chip]

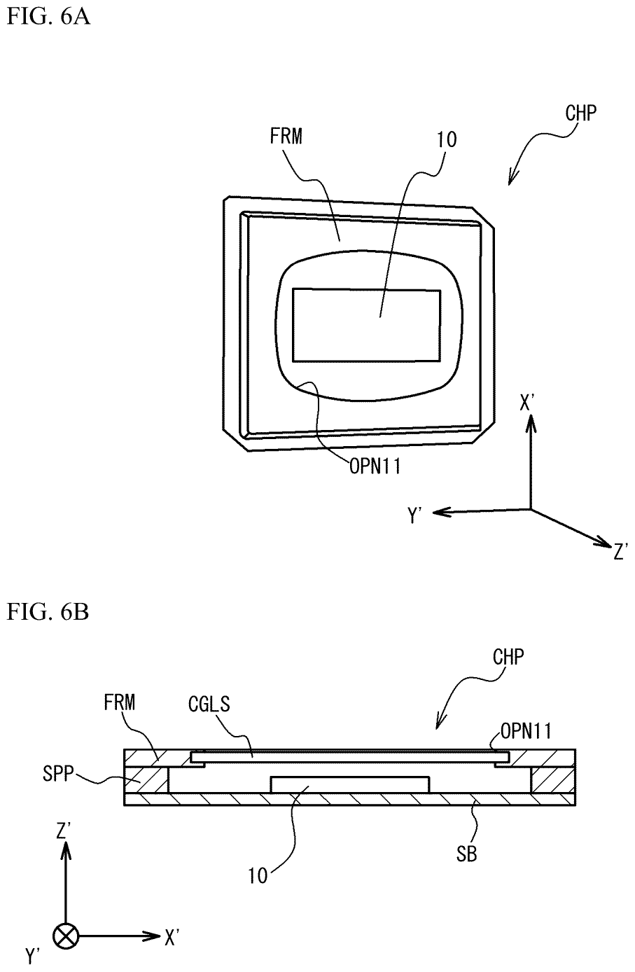

The DMD 10 is used in the form of a package (chip). FIG. 6A is a perspective view illustrating an example of a DMD chip CHP including the DMD 10, and FIG. 6B is a diagram illustrating an example of an X′Z′ cross-section of the DMD chip CHP. In FIG. 6A and FIG. 6B, the direction orthogonal to the neutral plane of the DMD 10 is defined as the Z′-axis direction.

As illustrated in FIG. 6B, the DMD chip CHP includes the DMD 10, a frame body FRM surrounding the DMD 10, and a substrate SB on which the DMD 10 and the frame body FRM are mounted. In the present embodiment, the frame body FRM is supported by a support portion SPP. The support portion SPP is made of metal, glass material, resin, or the like. The frame body FRM and the support portion SPP may be integrated.

The frame body FRM has an opening OPN11. The DMD 10 overlaps the opening OPN11 of the frame body FRM. The reflectance of the frame body FRM with respect to the illumination light ILm is greater than the reflectance of the plurality of micromirrors Ms with respect to the illumination light ILm.

In the present embodiment, the DMD chip CHP includes a cover glass CGLS that protects the DMD 10. The cover glass CGLS is supported by the frame body FRM. The cover glass CGLS is not limited to glass as long as it is a transparent member that transmits the illumination light ILm, and may be, for example, quartz or the like. The cover glass CGLS may be omitted.

Although only the DMD 10 is illustrated in FIG. 4, in practice, the DMD chip CHP is attached to a fine movement stage 10S provided on a mount portion 10M, which is fixed to a support column of the illumination unit ILU. As the fine movement stage 10S, for example, a fine movement stage as disclosed in International Publication No. 2006/120927 can be used, which is a combination of a parallel link mechanism and an extendable and contractible piezoelectric element. This enables fine adjustment of the position and orientation of the DMD 10.

At the position of the neutral plane of the DMD 10, the area on the X′Y′ plane illuminated with the illumination light ILm is referred to as an illumination field area. In the present embodiment, the illumination field area is set so that the entire DMD 10 is illuminated with the illumination light ILm even when the position of the DMD 10 is shifted in the X′-axis direction, the Y′-axis direction, and the θz direction by the fine movement stage DMD10. That is, the illumination field area is an area obtained by adding the movable range of the DMD 10 to the dimensions of the DMD 10 in the X′-axis direction and the Y′-axis direction, and the size of the illumination field area is larger than the size of the DMD 10. In other words, the illumination light ILm illuminates the DMD10 and the vicinity of the DMD 10.

When the size of the illumination field area is larger than the size of the DMD 10, part of the illumination light ILm enters the frame body FRM of the DMD chip CHP and is reflected by the frame body FRM, and scattered light (flare light) is generated, which may become stray light. The generation of stray light adversely affects the exposure result.

Therefore, in the present embodiment, in order to inhibit the generation of stray light, a light-shielding cover CVR that restricts the incidence of the illumination light ILm to the frame body FRM is provided (see FIG. 4). In the following description, the DMD chip CHP and the light-shielding cover CVR may be collectively referred to as a spatial light modulator unit SLMU.

As illustrated in FIG. 4, the light-shielding cover CVR is located on a side of the DMD chip CHP where the illumination light ILm enters the DMD 10. The light-shielding cover CVR is attached to the DMD chip CHP. The light-shielding cover CVR is preferably disposed away from the frame body FRM and the cover glass CGLS. By disposing the light-shielding cover CVR in this manner, the light-shielding cover CVR can be separated from the DMD 10, and the influence of heat absorbed by the light-shielding cover CVR on the DMD 10 can be reduced.

In the present embodiment, the reflectance of the light-shielding cover CVR with respect to the illumination light ILm is less than the reflectance of the plurality of micromirrors Ms with respect to the illumination light ILm. More specifically, the light-shielding cover CVR is subjected to a low reflection treatment (black chromium plating or the like) so that the reflectance to the illumination light ILm is 20% or less, preferably about 10% or less. This can inhibit the generation of scattered light due to reflection of the illumination light ILm by the light-shielding cover CVR. The entire light-shielding cover CVR may be subjected to the low reflection treatment, but at least the surface (surface on the −Z side) of the light-shielding cover CVR on which the illumination light ILm is incident is to be subjected to the low reflection treatment.

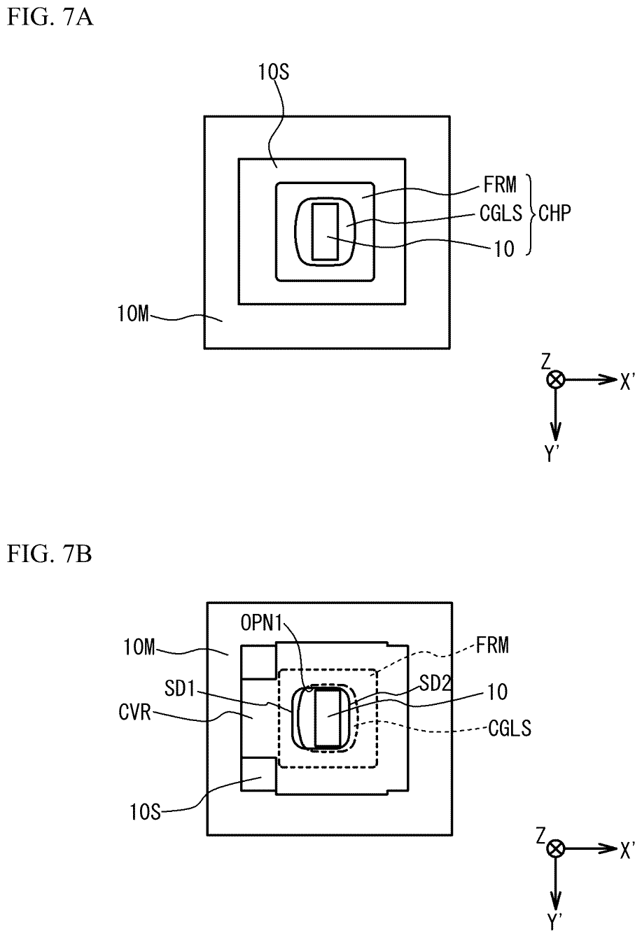

FIG. 7A illustrates the DMD chip CHP to which the light-shielding cover CVR is not attached as viewed from the −Z direction, and FIG. 7B is a view of the DMD chip CHP to which the light-shielding cover CVR is attached as viewed from the −Z direction. In FIG. 7B, the components of the DMD chip CHP hidden by the light-shielding cover CVR are indicated by dotted lines.

As illustrated in FIG. 7B, an opening OPN1 is formed in the light-shielding cover CVR (the light-shielding cover CVR has the opening OPN1). The illumination light ILm enters the DMD 10 through the opening OPN1. As illustrated in FIG. 7B, the opening OPN1 of the light-shielding cover CVR overlaps the frame body FRM.

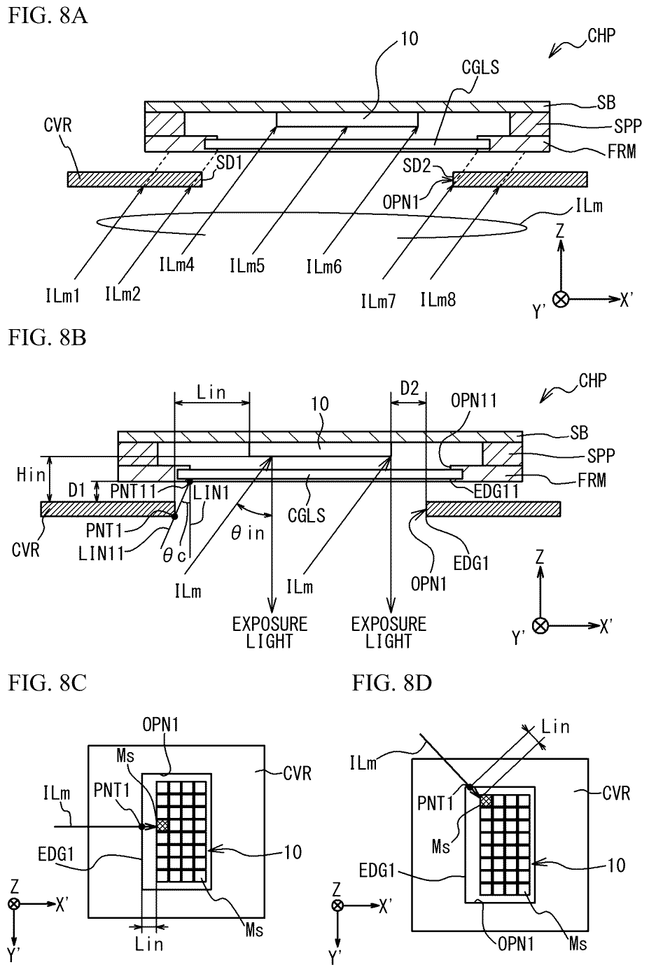

FIG. 8B is a cross-sectional view for describing the arrangement of the DMD chip CHP and the light-shielding cover CVR, and FIG. 8B is a cross-sectional view for describing the size of the opening OPN1 of the DMD chip CHP and the positional relationship between the DMD chip CHP and the opening OPN1. FIG. 8A and FIG. 8B illustrate a case where the illumination light ILm enters the DMD 10 from a direction parallel to the X′-axis.

As illustrated in FIG. 8A, when viewed from the incident direction of the illumination light ILm, the portion other than the opening OPN1 of the light-shielding cover CVR overlaps the frame body FRM of the DMD chip CHP.

Accordingly, the illumination light ILm1, the illumination light ILm2, the illumination light ILm7, and the illumination light ILm8, which would enter the frame body FRM if the light-shielding cover CVR is not installed, are blocked from entering the frame body FRM by the light-shielding cover CVR. This inhibits the generation of scattered light due to the illumination light ILm1, the illumination light ILm2, the illumination light ILm7, and the illumination light ILm8 being reflected by the frame body FRM.

Further, the portion other than the opening OPN1 of the light-shielding cover CVR does not overlap the DMD 10 when viewed from the incident direction of the illumination light ILm. Accordingly, the illumination light ILm4 to the illumination light ILm6 can enter the DMD 10.

As illustrated in FIG. 8B, when a distance between a plane that includes a point closest to the substrate SB in the reflection surfaces of the micromirrors Ms when the micromirrors Ms of the DMD 10 are in the ON state and is parallel to the surface of the substrate SB or a plane including the reflection surfaces of the micromirrors Ms when the reflection surfaces of the micromirrors Ms of the DMD 10 are parallel to the surface of the substrate SB and the +Z-side face of the light-shielding cover CVR is represented by Hin, and a distance between the −Z-side face of the frame body FRM and the +Z-side face of the light-shielding cover CVR is represented by D1, Hin>D1 is satisfied.

Further, the incident angle of the illumination light ILm to the reflection surface of the micromirror Ms when the reflection surface of the micromirror Ms is parallel to the surface of the substrate SB is represented by θin (=θα). In the present embodiment, θin is twice the inclination angle of the reflection surface of the micromirror Ms when the micromirror Ms is in the ON state. The angle θin may be set in consideration of an error (for example, ±0.5°) of the inclination angle of the reflection surface of the micromirror Ms when the micromirror Ms is in the ON state. In addition, when viewed from the direction (Z-axis direction) perpendicular to the surface of the substrate SB, tan θin<Lin/Hin is satisfied, where Lin is the distance between a point PNT1 on the edge forming the opening OPN1 and the micromirror Ms closest to the point PNT1 among the plurality of micromirrors Ms. Here, the point PNT1 on the edge forming the opening OPN1 will be described with reference to FIG. 8C and FIG. 8D.

FIG. 8C and FIG. 8D illustrate the DMD10 and the opening OPN1 as viewed from the −Z direction. In FIG. 8C, the illumination light ILm enters the DMD 10 from the direction parallel to the X′-axis. In this case, in the X′Y′ plane, a point where the edge EDG1 forming the opening OPN1 and the line indicating the optical axis of the incident light ILm intersect each other is the point PNT1. In FIG. 8C, the micromirror Ms closest to the PNT1 is indicated by hatching.

In FIG. 8D, the illumination light ILm enters the DMD 10 from a direction inclined with respect to the X′-axis (or the Y′-axis). In this case, in the X′Y′ plane, a point where the edge EDG1 forming the opening OPN1 and the line indicating the optical axis of the incident light ILm intersect each other is the point PNT1. In FIG. 8D, the micromirror Ms closest to the PNT1 is indicated by hatching.

By satisfying tan θin<Lin/Hin, the illumination light ILm is not blocked from entering the DMD 10 and the generation of scattered light caused by the illumination light ILm being reflected by the frame body FRM is inhibited. This can inhibit the generation of stray light.

A point that is on the edge EDG11 forming the opening OPN1 of the frame body FRM of the DMD chip CHP, and exists in a plane that includes the line connecting the point PNT on the edge EDG1 of the opening OPN1 of the light-shielding cover CVR and the micromirror Ms closest to the point PNT1 and is perpendicular to the surface of the substrate SB is defined as PNT11. In this case, the inclination angle θc of the line LIN11 connecting the point PNT11 and the point PNT1 with respect to the line LIN1 perpendicular to the surface of the substrate SB is smaller than θin. This prevents the incident illumination light ILm from being blocked from reaching the DMD 10, while also inhibiting the generation of scattered light caused by the illumination light ILm being reflected by the frame body FRM.

Further, of two sides SD1 and SD2 extending in the Y′-axis direction of the opening OPN1 (see FIG. 8A), a distance Lin in the X′-axis direction between the side SD1 on the incident side of the illumination light ILm and the DMD 10 is longer than a distance D2 in the X′-axis direction between the other side SD2 and the DMD 10 (see FIG. 8B). This can inhibit vignetting of the illumination light ILm obliquely incident on the DMD 10 by the light-shielding cover CVR.

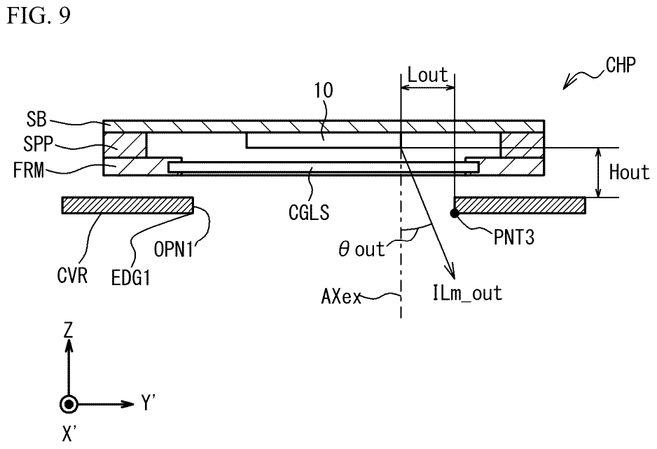

The opening OPN1 of the light-shielding cover CVR allows the illumination light (hereinafter referred to as discarded light) ILm_out reflected by the OFF-state micromirrors Ms to pass therethrough. FIG. 9 is a diagram illustrating a relationship between the arrangement of the opening OPN1 and the DMD 10 and the discarded light ILm_out. In FIG. 9, the discarded light ILm_out travels in the Y′-axis direction.

Represented by Hout is the distance between a plane that includes a point closest to the substrate SB in the reflection surface of the micromirror Ms when the micromirror Ms of the DMD 10 is in the OFF state and is parallel to the surface of the substrate SB, or a plane including the reflection surface of the micromirror Ms when the reflection surface of the micromirror Ms of the DMD 10 is set to parallel to the surface of the substrate SB, and the +Z-side surface of the light-shielding cover CVR. In addition, in a plane (X′Y′ plane in FIG. 9) that includes the optical axis AXex of the exposure light and the optical axis of the discarded light ILm_out and is perpendicular to the surface of the substrate SB, an angle between the optical axis AXex of the exposure light and the optical axis of the discarded light ILm_out is denoted by θout. Denoted by Lout is the distance between a point PNT3 at which a plane (X′Y′ plane in FIG. 9) that includes the optical axis AXex of the exposure light and the optical axis of the discarded light ILm_out and is perpendicular to the surface of the substrate SB intersects the edge EDG1 forming the opening OPN1 and the micromirror Ms closest to the point PNT3 among the plurality of micromirrors Ms. In this case, tan θout<Lout/Hout is satisfied. This allows the discarded light ILm_out to enter the light absorber (not illustrated) without blocking the travel of the illumination light ILm_out reflected by the micromirror Ms in the OFF state. The direction in which the discarded light ILm_out reflected by the OFF-state micromirror Ms travels is not limited to the Y′-axis direction, and depends on the setting of the DMD 10. Even when the traveling direction of the discarded light ILm_out is not the Y′-axis direction, tan θout<Lout/Hout is to be satisfied, where θout is the angle between the optical axis AXex of the exposure light and the optical axis of the discarded light ILm_out, and Lout is the distance between the point at which the plane that includes the optical axis AXex of the exposure light and the optical axis of the discarded light ILm_out and is perpendicular to the surface of the substrate SB intersects the edge EDG1 forming the opening OPN1 and the micromirror Ms closest to the point among the plurality of micromirrors Ms of the DMD 10.

Although the case where the light-shielding cover CVR is attached to the DMD chip CHP has been described, the light-shielding cover CVR may be attached to a member other than the DMD chip CHP. In this case, the light-shielding cover CVR is fixed so that the positional relationship between the opening OPN1 and the DMD 10 does not change relatively. For example, the light-shielding cover CVR may be fixed to the fine movement stage 10S. Alternatively, the light-shielding cover CVR may be fixed to a member other than the DMD chip CHP and the fine movement stage 10S, and in this case, the light-shielding cover CVR may be shifted in accordance with the shift of the position of the DMD 10 by the fine movement stage 10S.

### [Configuration of Projection Unit]

Referring back to FIG. 4, the projection unit PLU attached to the lower side of the optical surface plate 5 is configured as a both-side telecentric imaging projection lens system including a first lens group 116 and a second lens group 118 arranged along an optical axis AXa parallel to the Z-axis. The first lens group 116 and the second lens group 118 are configured to be moved in parallel by a fine actuator in a direction along the Z-axis (optical axis AXa) with respect to a support column fixed to the lower side of the optical surface plate 5. The projection magnification Mp of the imaging projecting lens system by the first lens group 116 and the second lens group 118 is determined by the relationship between the arrangement pitches Pdx and Pdy of the micromirrors of the DMD 10 and the minimum line width (minimum pixel dimension) Pg of the pattern projected in the projection area IAn (n=1 to 27) on the substrate P.

For example, when the required minimum line width (minimum pixel dimension) Pg is 1 μm and the arrangement pitches Pdx and Pdy of the micromirrors are 5.4 μm, the projection magnification Mp is set to about ⅙ in consideration of the inclination angle θk of the projection area IAn (DMD 10) in the XY plane described with reference to FIG. 3. The imaging projection lens system including the lens groups 116 and 118 forms an inverted/reversed reduced image of the entire mirror surface of the DMD 10 on the projection area IA18 (IAn) on the substrate P.

The first lens group 116 of the projection unit PLU is finely movable in the direction of the optical axis AXa by an actuator in order to finely adjust the projection magnification Mp (about ± several tens of ppm), and the second lens group 118 is finely movable in the direction of the optical axis AXa by an actuator in order to adjust the focus at high speed. Furthermore, in order to measure the positional change of the surface of the substrate P in the Z-axis direction with an accuracy of submicron or less, a plurality of oblique-incidence focus sensors 120 are provided on the lower side of the optical surface plate 5. The plurality of focus sensors 120 measure the overall positional change of the substrate P in the Z-axis direction, the positional change of the partial region on the substrate P in the Z-axis direction corresponding to each of the projection areas IAn (n=1 to 27), the partial inclination change of the substrate P, or the like.

Since the illumination unit ILU and the projection unit PLU as described above need to incline the projection area IAn by the angle θk in the XY plane as described in FIG. 3 above, the DMD 10 and the illumination unit ILU (at least the optical path section from the mirror 102 to the mirror 112 along the optical axis AXc) in FIG. 4 are arranged so as to be inclined by the angle θk in the XY plane as a whole.

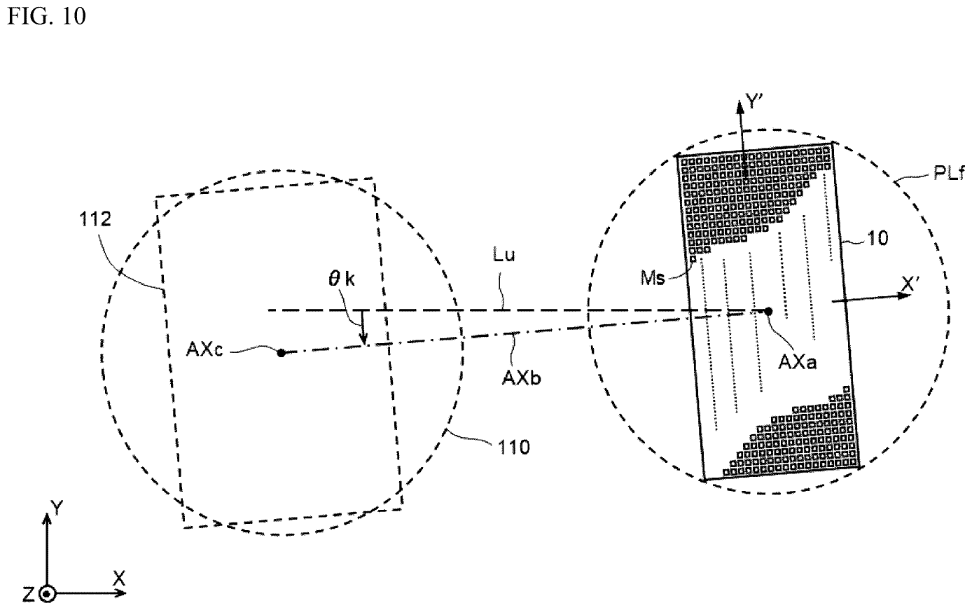

FIG. 10 schematically illustrates the state where the DMD 10 and the projection unit PLU are inclined by an angle θk within the XY plane. In FIG. 10, the orthogonal coordinate system XYZ is the same as the coordinate systems XYZ in FIG. 1 to FIG. 4, and the arrangement coordinate system X′Y′ of the micromirrors Ms of the DMD 10 is the same as the coordinate system X′Y′ illustrated in FIG. 3. The circle enclosing the DMD 10 is the image field PLf on the object side of the projector unit PLU, at the center of which the optical axis AXa is located. On the other hand, the optical axis AXb, which is the optical axis AXc that passes through the condenser lens system 110 of the illumination unit ILU and is bent by the inclined mirror 112, is arranged so as to be inclined by an angle θk from the line Lu parallel to the X-axis when viewed in the XY plane.

A light beam (that is, a spatially modulated light beam) formed only by the light reflected from the micromirror Ms in the ON state among the micromirrors Ms of the DMD 10 is irradiated onto a region on the substrate P optically conjugate with the micromirror Ms through the projection unit PLU. Thereby, the pattern generated by the DMD 10 is formed on the substrate P.

As described above in detail, the spatial light modulator unit SLMU according to the present embodiment includes the DMD chip CHP, which includes the DMD 10 having the plurality of micromirrors Ms arranged two dimensionally, the frame body FRM surrounding the DMD 10, and the substrate SB on which the DMD 10 and the frame body FRM are mounted, and the light-shielding cover CVR that is located on the side of the DMD chip CHP where the illumination light ILm enters the DMD 10, attached to the DMD chip CHP, and configured to restrict the entry of the illumination light ILm into the frame body FRM, wherein the light-shielding cover CVR has the opening OPN1, and the illumination light ILm enters the DMD 10 through the opening OPN1. This inhibits stray light from being generated by the generation of the scattered light due to the illumination light ILm being reflected by the frame body FRM.

In the present embodiment, the opening OPN1 of the light-shielding cover CVR overlaps the frame body FRM. This can inhibit the illumination light ILm to be incident on the DMD 10 from being vignetted by the light-shielding cover CVR.

In the present embodiment, the distance Hin between the light-shielding cover CVR and the DMD10 is greater than the distance D1 between the light-shielding cover CVR and the frame body FRM. This can inhibit the illumination light ILm to be incident on the DMD10 from being vignetted by the light-shielding cover CVR. Depending on the size of the opening OPN1, the distance Hin between the light-shielding cover CVR and the DMD 10 may be adjusted to be equal to the distance D1 between the light-shielding cover CVR and the frame body FRM.

In the present embodiment, the exposure device EX includes the spatial light modulator unit SLMU, the illumination unit ILU that illuminates the DMD chip CHP with the illumination light ILm, and the fine movement stage 10S that mounts the DMD chip CHP and moves in a plane parallel to the substrate SB. This allows the position of the DMD 10 to be shifted.

In the present embodiment, the illumination unit ILU illuminates the DMD 10 and the vicinity of the DMD 10. This inhibits the occurrence of a region that is not illuminated with the illumination light ILm in the DMD 10 even when the position of the DMD 10 is shifted.

In the present embodiment, the exposure device EX includes the DMD chip CHP including the DMD 10 having the plurality of micromirrors Ms arranged two dimensionally and the frame body FRM surrounding the DMD 10, the illumination unit ILU that illuminates the DMD chip CHP with the illumination light ILm, the light-shielding cover CVR that prevents the illumination light ILm from entering the frame body FRM, and the projection unit PLU that projects the light from the DMD 10 onto the substrate P scanned in the scanning direction. Since the light-shielding cover CVR prevents the illumination light ILm from entering the frame body FRM, it is possible to inhibit the generation of stray light due to the generation of scattered light caused by the reflection of the illumination light ILm by the frame body FRM.

In the present embodiment, the light-shielding cover CVR has the substantially quadrangular opening OPN1 formed therein to allow the illumination light ILm to pass therethrough, and when viewed from the incident direction of the illumination light ILm onto the DMD chip CHP, the portion of the light-shielding cover CVR other than the opening OPN1 overlaps the frame body FRM of the DMD chip CHP. This inhibits the generation of the stray light due to the generation of the scattered light caused by the reflection of the illumination light ILm by the frame body FRM.

In the above first embodiment, the light-shielding cover CVR overlaps the frame body FRM when viewed from the incident direction of the illumination light ILm so that the illumination light ILm is not incident on the frame body FRM of the DMD chip CHP, but this does not intend to suggest any limitation. For example, the light-shielding cover CVR may be omitted, and the frame body FRM may be subjected to a low reflection treatment (black chromium plating or the like) such that the reflectance to the illumination light ILm is 20% or less, preferably about 10% or less. Even in this case, it is possible to inhibit the generation of scattered light (flare light) due to the reflection of the illumination light ILm by the frame body FRM. Even if the frame body FRM has low reflection, the light-shielding cover CVR may be provided. The influence of heat on the DMD 10 can be reduced.

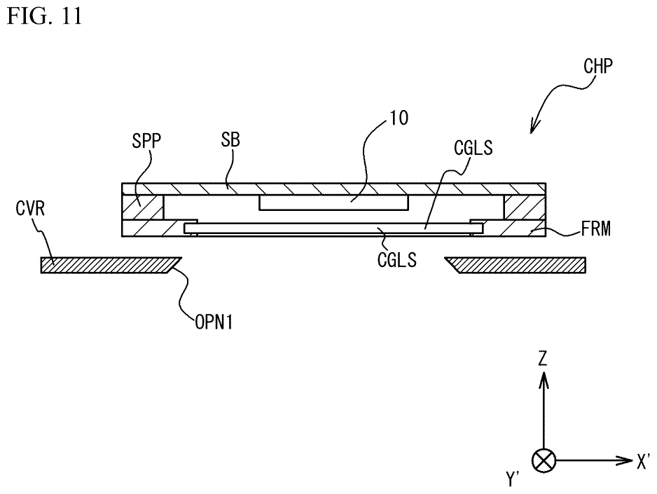

In the above embodiment, the size of the opening OPN1 of the light-shielding cover CVR on the DMD 10 side is substantially the same as the size of the opening OPN1 on the opposite side to the DMD 10 (the inner wall of the opening OPN1 of the light-shielding cover CVR is substantially perpendicular to the neutral plane (X′Y′ plane) of the DMD10), but this does not intend to suggest any limitation. For example, as illustrated in FIG. 11, the size of the opening OPN1 on the side opposite to the DMD 10 may be larger than the size of the opening OPN1 on the DMD 10 side. That is, the inner wall of the opening OPN1 may be inclined. This can inhibit the illumination light ILm to be incident on the DMD 10 from being vignetted by the light-shielding cover CVR.

In the above embodiment, the light-shielding cover CVR is provided to prevent the illumination light ILm from entering the frame body FRM of the DMD chip CHP, but this does not intend to suggest any limitation. For example, the light-shielding cover may be arranged to prevent scattered light (flare light) generated by reflection of the illumination light ILm by the frame body FRM from traveling to the substrate P. In this case, the light-shielding cover may be disposed at a position where the scattered light is blocked from traveling but the exposure light reflected by the micromirror Ms in the ON state is not blocked from traveling.

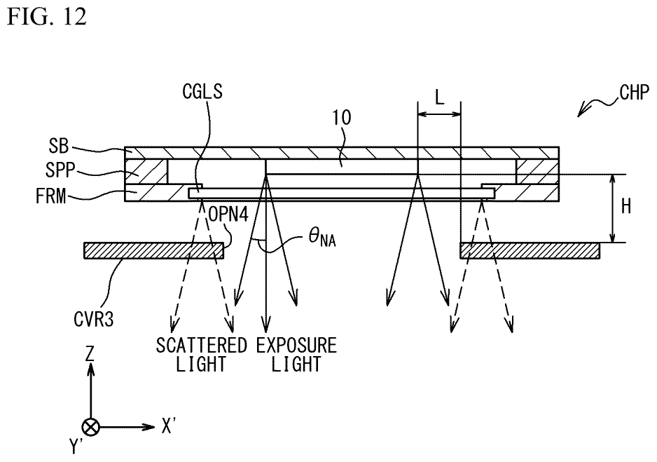

FIG. 12 is a diagram for describing a light-shielding cover CVR3 that blocks the progress of scattered light. In FIG. 12, the scattered light is indicated by broken lines, and the exposure light is indicated by solid lines.

The light-shielding cover CVR3 has an opening OPN4 that allows light (exposure light) reflected by the micromirror Ms in the ON state to pass therethrough. The size of the opening OPN4 of the light-shielding cover CVR3 and the positional relationship between the DMD 10 and the light-shielding cover CVR3 are determined so as to prevent the scattered light from traveling but not to prevent the exposure light reflected by the micromirror Ms in the ON state from traveling. Specifically, the size of the opening OPN4 and the positional relationship between the light-shielding cover CVR3 and the DMD 10 are determined so as to satisfy tan θ_{NA}<L/H. Here, L is the distance between the opening OPN4 of the light-shielding cover CVR3 and the DMD 10, and H is the distance between a plane including the reflection surfaces of the micromirrors Ms when the reflection surfaces of the micromirrors Ms of the DMD 10 are set to be parallel to the surface of the substrate SB and the +Z-side face of the light-shielding cover CVR3. Θ_{NA} is defined by the following equation.

$${θ}_{NA} = {sin}^{- 1} ( NA \times β / n )$$

Here, NA represents the numerical aperture of the projection unit PLU, n represents the refractive index of the optical path medium, and β represents the optical magnification. In this manner, the light-shielding cover CVR3 may be provided that prevents scattered light (flare light) generated by reflection of the illumination light ILm by the frame body FRM from traveling to the substrate P.

### Second Embodiment

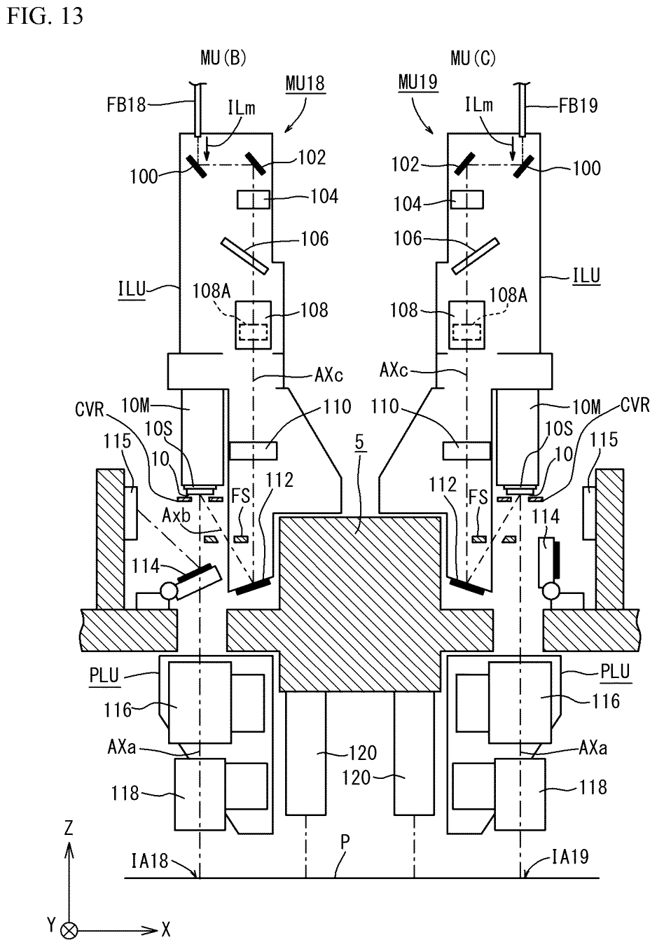

FIG. 13 is an optical arrangement diagram illustrating a specific configuration of a module MU18 in the exposure module MU(B) and a module MU19 in the exposure module MU(C) in the second embodiment, as viewed in the XZ plane. In the following description, an area on the substrate P conjugate with each micromirror Ms is referred to as a light irradiation area, and a set of light irradiation areas is referred to as a light irradiation area group. The projection area IAn coincides with the light irradiation area group. That is, the light irradiation area group on the substrate P has a large number of light irradiation areas arranged in the two-dimensional directions (the X′-axis direction and the Y′-axis direction).

The second embodiment is different from the first embodiment in that a field stop FS is arranged in the optical path of the illumination light ILm between the optical integrator 108 and the DMD 10.

### [Imaging Optical Path by DMD]

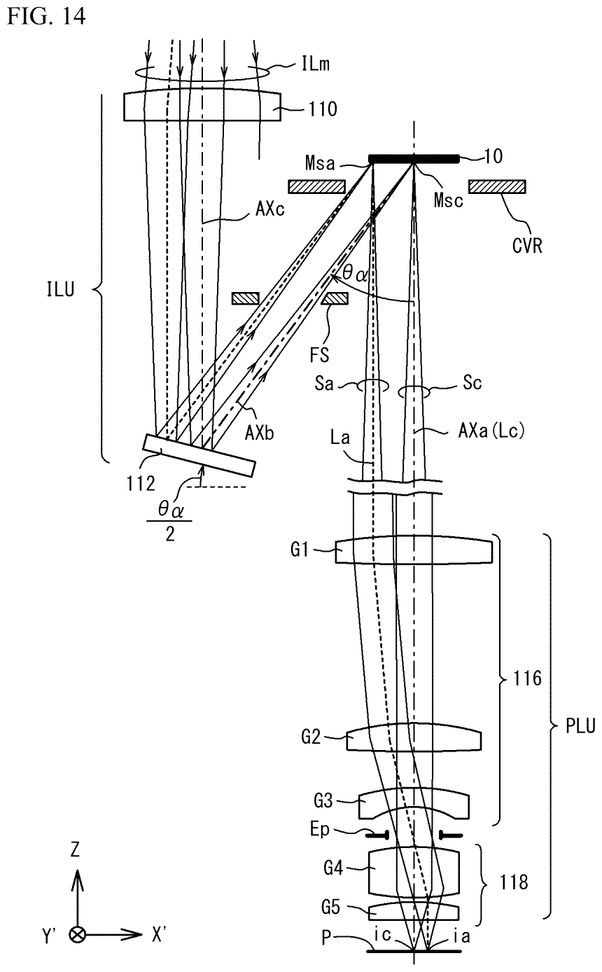

Referring to FIG. 14, the imaging state of the micromirror Ms of the DMD 10 by the projection unit PLU (imaging projecting lens system) will be described in detail. The orthogonal coordinate system X′Y′Z in FIG. 14 is the same as the coordinate system X′Y′Z illustrated in FIG. 3 and FIG. 10 above, and FIG. 14 illustrates the optical path from the condenser lens system 110 of the illumination unit ILU to the substrate P. The illumination light ILm from the condenser lens system 110 travels along the optical axis AXc, is totally reflected by the inclined mirror 112, and reaches the mirror surface of the DMD 10 along the optical axis AXb. Here, the micromirror Ms located at the center of the DMD 10 is denoted by Msc, the micromirror Ms located at the periphery is denoted by Msa, and the micromirrors Msc and Msa are in the ON state.

When the inclination angle of the micromirror Ms in the ON state is set to, for example, 17.5° as a standard value with respect to the X′Y′ plane (XY plane), the incident angle (the angle of the optical axis AXb from the optical axis AXa) θα of the illumination light ILm irradiated to the DMD 10 is set to 35.0° in order to cause the respective principal rays of the reflected light Sc and Sa from the respective micromirrors Msc and Msa to be parallel to the optical axis AXa of the projection unit PLU. Therefore, in this case, the reflection surface of the inclined mirror 112 is also arranged to be inclined by 17.5° (=θα/2) with respect to the X′Y′ plane (XY plane). The principal ray Lc of the reflected light Sc from the micromirror Msc is coaxial with the optical axis AXa, the principal ray La of the reflected light Sa from the micromirror Msa is parallel to the optical axis AXa, and the reflected light Sc and Sa enter the projection unit PLU with a predetermined numerical aperture (NA).

By the reflected light Sc, a reduced image ic of the micromirror Msc reduced at the projection magnification Mp of the projection unit PLU is formed on the substrate P in a telecentric state at the position of the optical axis AXa. Similarly, the reflected light Sa forms a reduced image ia of the micromirror Msa reduced at the projection magnification Mp of the projection unit PLU on the substrate P in a telecentric state at a position away from the reduced image ic in the +X′ direction. As an example, the first lens group 116 of the projection unit PLU includes two lens groups G1 and G2, and the second lens group 118 includes three lens groups G3, G4, and G5. An exit pupil (also simply referred to as a pupil) Ep is set between the lens group G3 and the lens group G4 of the second lens unit 118. A light-source image (a set of a large number of point light sources formed on the emission surface side of the MFE lens 108A) of the illumination light ILm is formed at the position of the pupil Ep, and the Koehler illumination configuration is achieved. The pupil Ep is also called an opening of the projection unit PLU, and the size (diameter) of the opening is one factor that defines the resolution capability of the projection unit PLU.

The specular reflection light from the ON-state micromirror Ms of the DMD 10 is set to pass through without being blocked by the maximum aperture (diameter) of the pupil Ep, and the numerical aperture NAi on the image side (substrate P side) in the equation R=k1·(λ/NAi) is determined by the maximum aperture of the pupil Ep and the length of the rear (image side) focal point of the projection unit PLU (lens groups G1 to G5 as the image forming projecting lens system). The numerical aperture NAo on the object plane (DMD 10) side of the projection unit PLU (lens groups G1 to G5) is expressed by the product of the projection magnification Mp and the numerical aperture NAi, and when the projection magnification Mp is ⅙, NAo=NAi/6.

In the configuration of the illumination unit ILU and the projection unit PLU illustrated in FIG. 13 and FIG. 14, the emission ends of the optical fiber bundles FBn (n=1 to 27) connected to the respective modules MUn (n=1 to 27) are set in an optically conjugate relationship with the emission end side of the MFE lens 108A of the optical integrator 108 by the input lens system 104, and the incidence end side of the MFE lens 108A is set in an optically conjugate relationship with the center of the mirror surface (neutral surface) of the DMD 10 by the condenser lens system 110. As a result, the illumination light ILm irradiated onto the entire mirror surface of the DMD 10 achieves a uniform illuminance distribution (e.g., intensity variation within ±1%) due to the action of the optical integrator 108. The emission end side of the MFE lens 108A and the surface of the pupil Ep of the projection unit PLU are set in an optically conjugate relationship by the condenser lens system 110 and the lens groups G1 to G3 of the projection unit PLU.

### [Line Pattern Exposure Process]

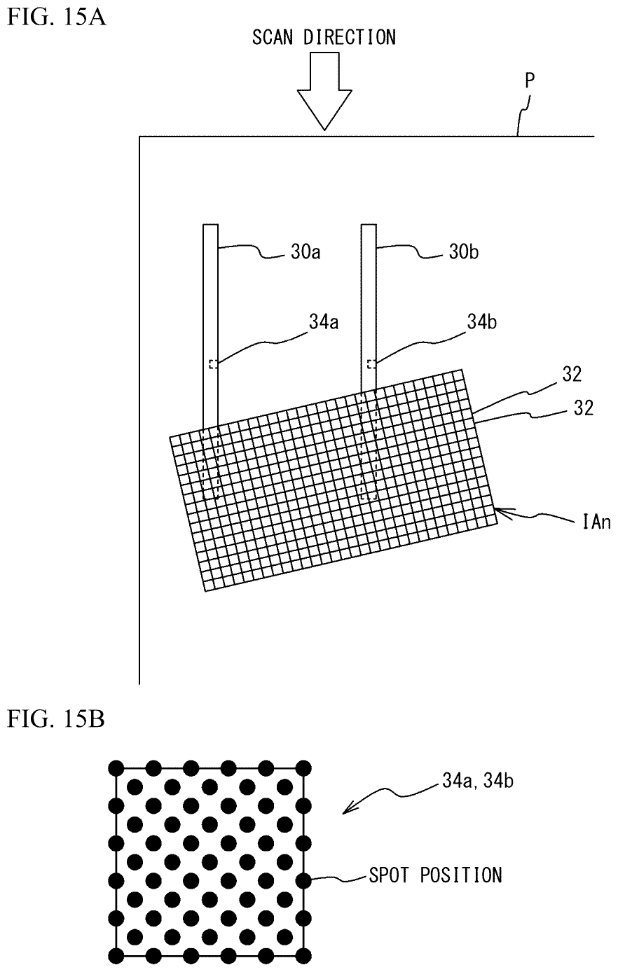

FIG. 15A is a diagram schematically illustrating a projection area (light irradiation area group) IAn and exposure target areas (areas to which a line pattern is exposed) 30a and 30b on the substrate P. In the present embodiment, the exposure target areas 30a and 30b are scanned with respect to the projection area (light irradiation area group) IAn, and the DMD 10 brings the micromirrors Ms corresponding to the light irradiation areas 32 into the ON state at the timing when the centers (referred to as a spot position) of the light illumination regions 32 included in the projection area (light irradiation area group) IAn are positioned within the exposure target areas 30a and 30b.

Here, as illustrated in FIG. 15B, attention is paid to a rectangular region 34a, which is a part of the line-shaped exposure target area 30a, and a rectangular region 34b, which is a part of the exposure target area 30b (see the broken line frames (reference numerals 34a and 34b) in FIG. 15A). The rectangular regions 34a and 34b are square regions each having a side of 1 μm, for example. The light irradiation area 32 corresponding to each micromirror Ms is also a square area having a side of 1 μm.

FIG. 15B illustrates a state in which the rectangular regions 34a and 34b are exposed in a state where spots positions are arranged at 61 locations (staggered arrangement) with 61 pulses. Here, there is a case where a difference (illuminance unevenness) occurs between the integrated illuminance (the sum of the exposure amounts) of the rectangular region 34a and the integrated illuminance of the rectangular region 34b due to manufacturing errors and assembly errors of the respective components and variations in optical characteristics of the optical components. That is, the integrated illuminance may vary depending on the position in the Y-axis direction, and the integrated illuminance distribution in the Y-axis direction may be non-uniform. It is desirable that the integrated illuminance distribution in the Y-axis direction is uniform.

Therefore, for example, when the integrated illuminance of the rectangular region 34a is higher than the integrated illuminance of the rectangular region 34b, it is conceivable to reduce the exposure amount of the rectangular region 34a and correct (reduce) the integrated illuminance of the rectangular region 34a by setting some of the micromirrors Ms to the OFF state when the rectangular region 34a is exposed.

However, for example, when the rectangular region 34a is exposed with 61 pulses and all the 61 pulses have equal illuminance, the change in the integrated illuminance by bringing one micromirror Ms into the OFF state is 1.64% (= 1/61×100). To achieve uniform integrated illuminance distribution, it is desirable to correct the integrated illuminance with higher resolution.

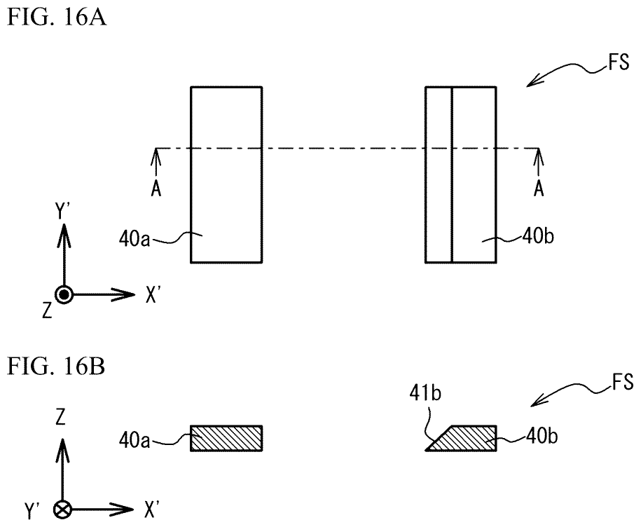

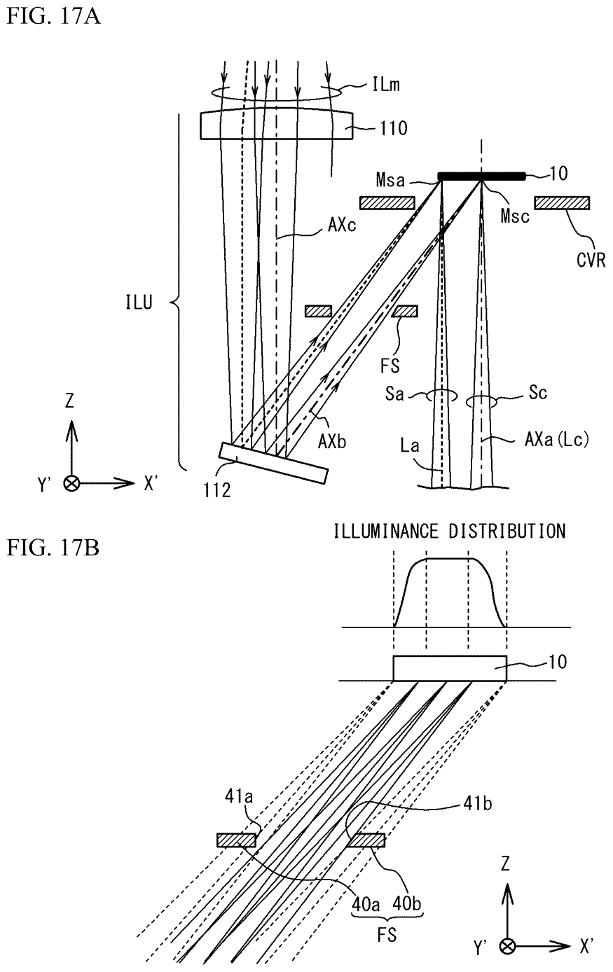

Therefore, in the present embodiment, the field stop FS is disposed on the optical path of the illumination light ILm between the optical integrator 108 and the DMD 10. FIG. 16A is a plan view of the field stop FS, and FIG. 16B is a cross-sectional view taken along line A-A of FIG. 16A. Further, FIG. 17A is a diagram for describing the arrangement of the field stop FS, and FIG. 17B is a diagram illustrating the illuminance distribution of the illumination light formed by the field stop FS.

As illustrated in FIG. 16A, the field stop FS includes a first member 40a and a second member 40b. The first member 40a is a quadrangular prism with a substantially rectangular cross-section, and the second member 40b is a quadrangular prism with a substantially right-angled trapezoidal cross-section.

Further, the side surface 41b (see FIG. 17B) on the illumination light ILm side of the second member 40b is inclined with respect to the lower surface so that the angle (internal angle) between the lower surface and the side surface 41b is an acute angle. This inhibits the illumination light ILm from being reflected by the side surface 41b of the field stop FS on the illumination light ILm side. In the present embodiment, the field stop FS is subjected to a low reflection treatment (black chromium plating or the like) so that the reflectance to the illumination light ILm is 20% or less, preferably about 10% or less. This can prevent the illumination light ILm from being reflected by the field stop FS to generate scattered light, thereby inhibiting generation of stray light.

In the present embodiment, the field stop FS is disposed between the inclined mirror 112 and the DMD 10. The field stop FS may be disposed at any position on the optical path of the illumination light ILm between the optical integrator 108 and the DMD 10. For example, the field stop FS may be disposed between the condenser lens system 110 and the inclined mirror 112, or may be disposed between the optical integrator 108 and the condenser lens system 110.

In the present embodiment, the field stop FS is attached to, for example, the DMD chip CHP so that the relative positional relationship with the DMD 10 does not change. The field stop FS may be attached to, for example, the fine movement stage 10S. Alternatively, the field stop FS may be fixed to a member other than the DMD chip CHP and the fine movement stage 10S, and in this case, the field stop FS may be shifted in accordance with the shift of the position of the DMD 10 by the fine movement stage 10S.

As illustrated in FIG. 17B, the first member 40a and the second member 40b extend in a direction (Y′-axis direction) substantially orthogonal to the scanning direction (X-axis direction) of the substrate P, of two axial directions (X′-axis direction and Y′-axis direction) that define the arrangement coordinates system X′Y′ of the micromirrors Ms. Thereby, the first member 40a and the second member 40b block a part of the illumination light ILm along the Y′-axis direction. This allows the illuminance of the illumination light ILm to be varied according to the position in the X′-axis direction.

The first member 40a and the second member 40b are arranged with a predetermined interval in the X′-axis direction orthogonal to the Y′-axis direction, and block a part of the illumination light ILm along the sides at both ends of the DMD 10 in the X′-axis direction. As a result, as illustrated in FIG. 17B, the illuminance distribution of the illumination light ILm in the X′-axis direction the illuminance distribution (top-hat-shaped illuminance distribution illustrated in FIG. 17B) where the illuminance is low at both ends of the DMD 10 in the X′-axis direction and is high in the central region. The illuminance distribution includes a region with illuminance greater than 0% and less than 50% of the maximum illuminance in the illuminance distribution. For example, the illuminance distribution may include a region with illuminance greater than 0% and less than 100% of the maximum illuminance in the illuminance distribution, may include a region with illuminance greater than 10% and less than 90% of the maximum illuminance in the illuminance distribution, or may include a region with illuminance greater than 50% and less than 90% of the maximum illuminance in the illuminance distribution.

In the present embodiment, the first member 40a and the second member 40b are disposed so that the lower surfaces thereof are parallel to the neutral surface of the DMD 10. This enables the influence of telecentricity to be made centrally symmetric.

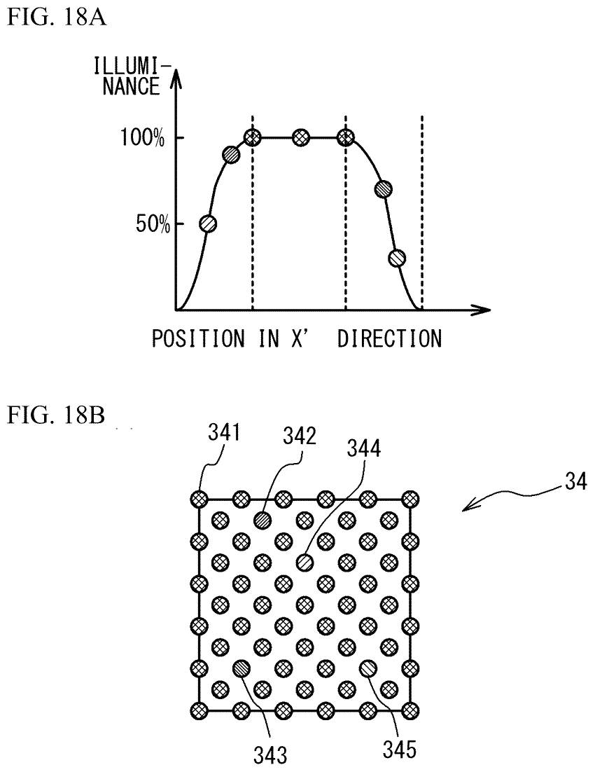

FIG. 18A illustrates an example of the illuminance distribution of the illumination light ILm, and FIG. 18B illustrates an example in which the rectangular region 34 is exposed using the illumination light ILm having the illuminance distribution illustrated in FIG. 18A. By irradiating the DMD 10 with the illumination light ILm having the illuminance distribution illustrated in FIG. 18A, the illuminance of the illumination light projected on each light irradiation area 32 can be made different.

In FIG. 18B, a spot position 342 is a spot position of the light irradiation area 32 onto which the illumination light having an illuminance of 90% is projected. A spot position 343 is a spot position of the light irradiation area 32 onto which the illumination light having an illuminance of 70% is projected, and a spot position 344 is a spot position of the light irradiation area 32 onto which the illumination light having an illuminance of 50% is projected. A spot position 345 is a spot position of the light irradiation area 32 onto which the illumination light having an illuminance of 30% is projected. A spot position 341 is a spot position of the light irradiation area 32 onto which the illumination light having an illuminance of 100% is projected, other than the spot positions 342 to 345.

In FIG. 18B, among the 61 spot positions, the number of the spot positions 342, 343, 344, and 345 is one each, and the number of the spot positions 341 is 57. In this case, for example, when the micromirror Ms corresponding to the light irradiation area 32 onto which the illumination light having an illuminance of 50% is projected is set to the OFF state, the integrated illuminance in the rectangular region 34 is reduced by 0.84% (=0.5/(57+0.9+0.7+0.5+0.3)×100). For example, when the micromirror Ms corresponding to the light irradiation area 32 onto which the illumination light having an illuminance of 30% is projected is set to the OFF state, the integrated illuminance in the rectangular region 34 is reduced by 0.505% (=0.3/(57+0.9+0.7+0.5+0.3)×100). Therefore, the integrated illuminance can be corrected with higher resolution than in the case where the integrated illuminance in the rectangular region 34 is corrected by using the illumination light having an illuminance distribution in which the illuminance does not vary in the X′-axis direction (the illuminance is constant in the X′-axis direction) and setting some of the micromirrors Ms of the DMD 10 to the OFF state. Further, by changing the combination of the micromirrors Ms to be set to the OFF state, the integrated illuminance can be corrected by a desired change amount.

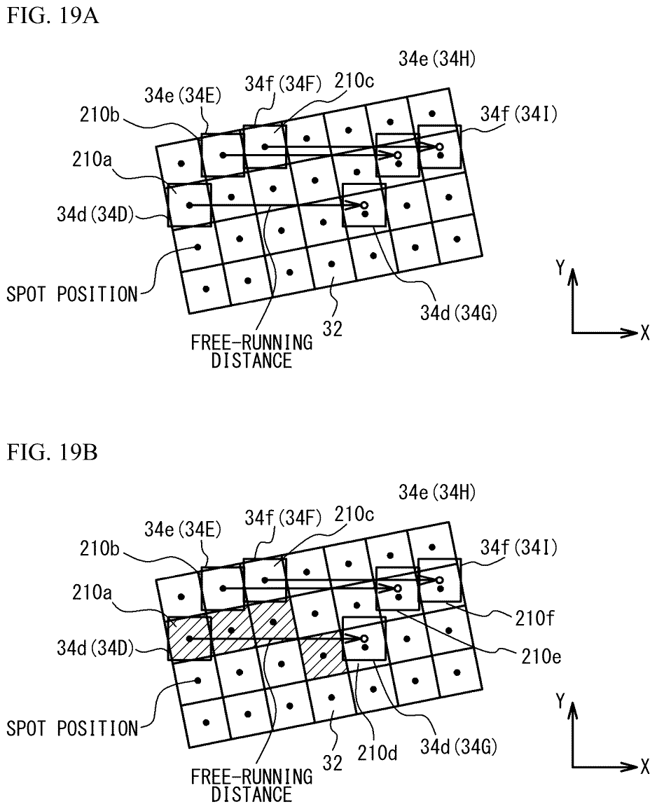

FIG. 19A is a diagram illustrating how rectangular regions 34d to 34f are exposed. For example, the DMD 10 brings the micromirrors Ms corresponding to the light irradiation areas 210a to 210c into the ON state at the timing when the rectangular regions 34d to 34f are at the positions 34D to 34F, respectively, and brings the micromirrors Ms corresponding to the light irradiation areas 210d to 210f into the ON state at the timing when the rectangular regions 34d to 34f are at the positions 34G to 34I. In this case, the rectangular regions 34d to 34f move by the free-running distance between the pulses.

Here, for example, it is assumed that, as a result of measuring the integrated illuminance of the rectangular region 34d, it is determined to correct the integrated illuminance by bringing the micromirror Ms corresponding to the light irradiation area 210a into the OFF state. FIG. 19B is a diagram illustrating how the rectangular regions 34d to 34f are exposed in a case where the integrated illuminance is corrected.

In this case, as illustrated in FIG. 19B, the micromirror Ms corresponding to the light irradiation area 210a is brought into the OFF state at the timing when the rectangular region 34d is at the position 34D, and the micromirror Ms corresponding to the light irradiation area 210d is brought into the ON state at the timing when the rectangular region 34d is at the position 34G. After the timing at which the rectangular region 34d is at the position 34D, the substrate P moves by the free-running distance, and exposure is not performed until the rectangular region 34a moves from the position 34D to the position 34G. Therefore, there are micromirrors Ms that are not used for exposure.

The micromirrors Ms that are not used for exposure are the micromirrors Ms that are continuous in the scanning direction for a distance corresponding to the free-running distance, and thus these micromirrors Ms are set to the OFF state. In FIG. 19B, the light irradiation areas corresponding to the micromirrors Ms in the OFF state are indicated by hatching.

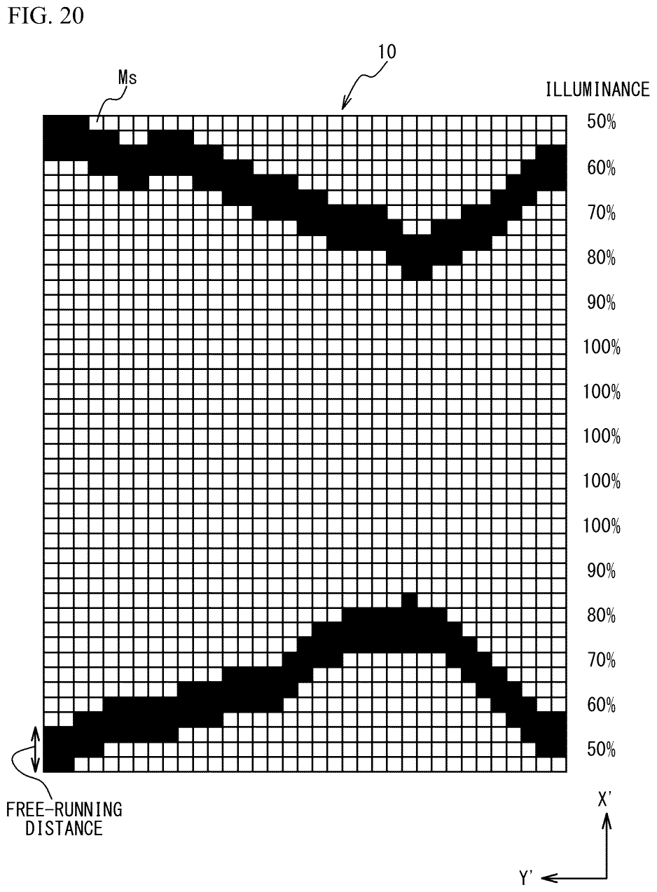

Furthermore, since it is unlikely that the illuminance distribution in the direction (Y-axis direction) perpendicular to the scanning direction would rapidly vary, the micromirrors Ms are also set to the OFF state continuously in the Y-axis direction. As a result, as illustrated in FIG. 20, the micromirrors Ms to be in the OFF state are continuous in the X′-axis direction and the Y′-axis direction, and form a substantially strip-shaped region having a width in the scanning direction. In FIG. 20, each square represents the micromirror Ms, and a black square represents the micromirror Ms in the OFF state.

For example, the spot interval (also referred to as a grid) is 1/10 of the rectangular region 34d (also referred to as a pixel), and it is necessary to determine the ON and OFF states for each spot (for each micromirror Ms). However, since the pixel size that is 10 times the spot interval is small, the ON state and the OFF state of the micromirror Ms may be determined for each pixel size, the ON state and the OFF state of the micromirror Ms may be determined for each larger size (region including a plurality of pixels), and the illuminance measurement may be performed in a unit of pixel (unit of rectangular region). For example, when the illuminance distribution is applied to 1/20 of the length of the DMD 10, the illuminance correction can be performed with a resolution of 0.1%, and therefore, if the illuminance uniformity has a variation of approximately 2% as a whole, the region to which the illuminance distribution is applied is sufficient to have that size (about 1/20 of the length of the DMD 10).

### [Configuration of Measurement Unit IU]

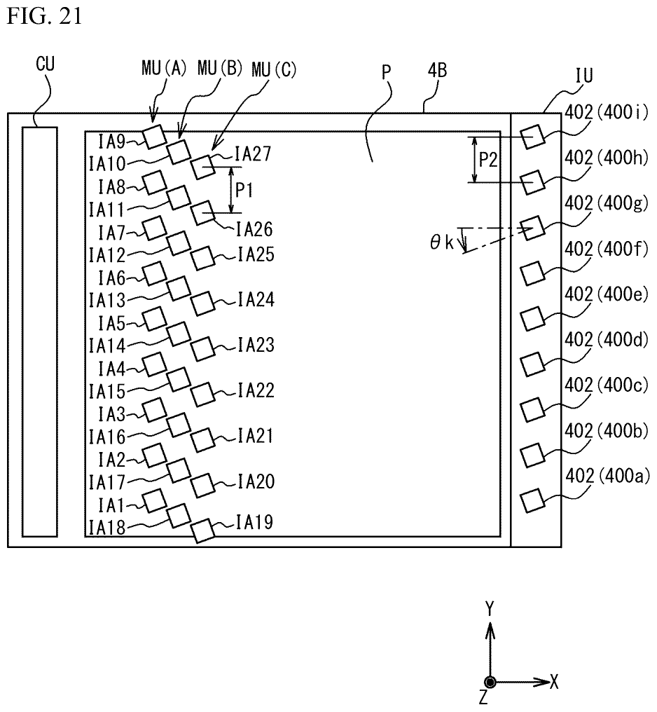

Next, the configuration of the measurement unit IU will be described. FIG. 21 is a view of the substrate holder 4B as viewed from the +Z direction. In the present embodiment, the measurement unit IU is provided on the opposite side of the substrate holder 4B from the calibration reference unit CU in the X-axis direction. The measuring unit IU may be provided on the same side as the calibration reference unit CU.

As illustrated in FIG. 21, in the measurement unit IU, a plurality of measurement devices 400a to 400i are arranged in a direction (Y-axis direction) perpendicular to the scanning exposure direction (X-axis direction) of the substrate P. The measurement devices 400a to 400i measure the illuminance of each micromirror Ms of the DMDs 10 of the modules MU1 to MU27, respectively. The measurement devices 400a to 400i can be arranged on the substrate holder 4B as illustrated in FIG. 21, but may be arranged on the XY stage 4A or in the projection unit PLU.

The measurement devices 400a to 400i are provided so as to correspond to the modules MU1 to MU9 included in the exposure module group MU(A), for example. That is, the measurement devices are arranged so that a pitch P1 between the centers of the modules adjacent to each other in the Y-axis direction is equal to a pitch P2 between the centers of the measurement devices adjacent to each other in the Y-axis direction. In the following description, the measurement devices 400a to 400i will be referred to as a measurement device 400 unless otherwise specified. The measurement devices 400 may be provided to correspond to the modules MU1 to MU27, respectively. That is, 27 measurement devices 400 may be arranged in the measurement unit IU. The number of measurement devices 400 is not limited to the number illustrated in FIG. 21, and may be eight or less, or ten or more. For example, within the stroke of the XY stage 4A, the XY stage 4A can be stepped to measure the illuminance of each micromirror Ms of the DMDs 10 of the modules MU1 to MU27, and thus the number of the measurement devices 400 can be further reduced.

In the present embodiment, as illustrated in FIG. 21, the measurement device 400 is inclined in the XY plane by the angle (θk: see FIG. 10) by which the DMD 10 is inclined in the XY plane. The measurement device 400 does not have to be arranged to be inclined in the XY plane.

The measurement device 400 includes, for example, a photosensor 402. For example, when one of the micromirrors Ms of the DMD 10 is set to the ON state and the other micromirrors Ms are set to the OFF state, the measurement device 400 repeats a process of measuring and storing the illuminance (power) of the pattern image (exposure light) projected by the micromirror Ms in the ON state, by the number of micromirrors Ms. As a result, measurement results in which each micromirror is associated with the illuminance of the exposure light is obtained. An aperture plate such as a pin hole for limiting a measurement point may be provided on a plane conjugate with the DMD 10.

The measurement device 400 may include, for example, an image sensor (CCD or CMOS) having pixels corresponding to the respective micromirrors Ms of the DMD 10. In this case, all the micromirrors Ms are set to the ON state, and the illuminance of the pattern image projected by the corresponding micromirrors Ms is measured in each pixel.

The measurement device 400 may include, for example, an image sensor having a smaller number of pixels than the number of micromirrors Ms of the DMD 10. In this case, a plurality of micromirrors Ms are associated with one pixel of the image sensor. In this case, the illuminance of the pattern image projected by a set of a plurality of the micromirrors Ms is measured in each pixel.

The integrated illuminance at each position in the Y-axis direction can be calculated based on the measurement result of the measurement device 400. For example, the measurement device 400 may be an integrating illuminometer, and may measure the integrated illuminance at each position in the Y-axis direction. Alternatively, a long slit may be provided, and the integrated illuminance may be measured by scanning the slit.

### [Configuration of Exposure Control Device]

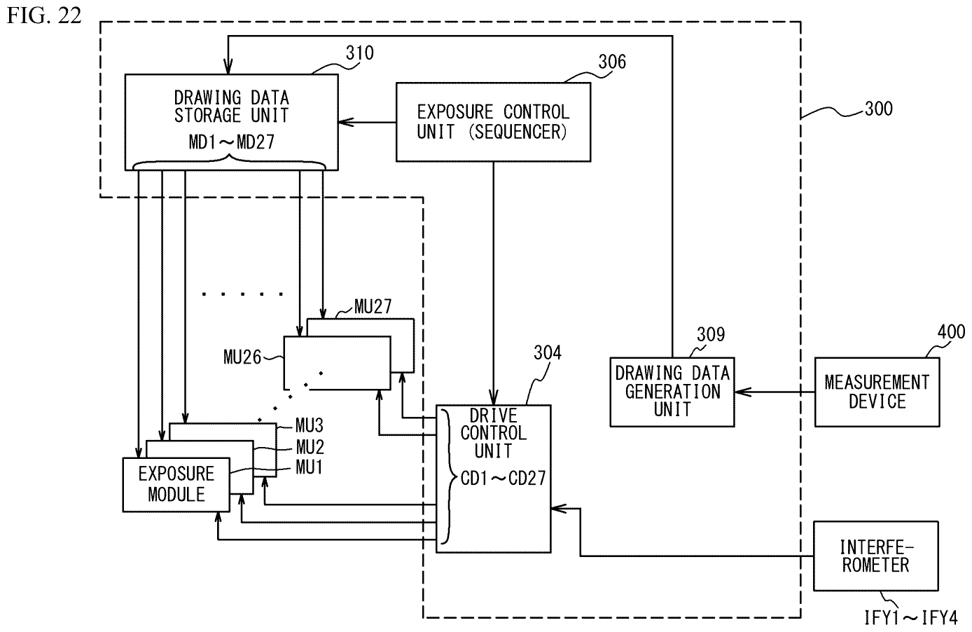

Various processes including the scanning exposure process performed in the exposure device EX having the above configuration are controlled by the exposure control device 300. FIG. 22 is a functional block diagram illustrating the functional configuration of the exposure control device 300 provided in the exposure device EX according to the present embodiment.

The exposure control device 300 includes a drawing data generation unit 309, a drawing data storage unit 310, a drive control unit 304, and an exposure control unit 306.

The drawing data generation unit 309 generates drawing data of a pattern for a display panel to be exposed by each of the plurality of the modules MUn (n=1 to 27). The drawing data is data for switching the ON and OFF states of each micromirror Ms of the DMD 10.

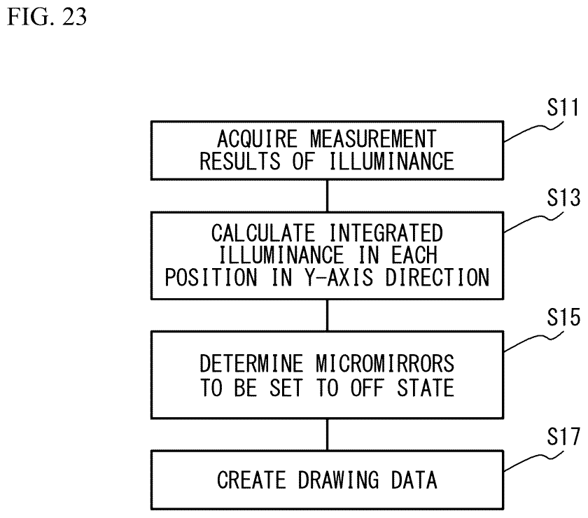

The drawing data generation unit 309 generates drawing data, for example, according to the flowchart illustrated in FIG. 23. First, in step S11, the drawing-data generation unit 309 acquires, from the measurement device 400, the measurement results of the illuminance of the pattern image projected by each micromirror Ms.

Then, in step S13, the drawing data generation unit 309 predicts the integrated illuminance at each position in the Y-axis direction based on the measurement result acquired in step S11. For example, the drawing data generation unit 309 predicts the integrated illuminance for each square region having a side length of 1 μm arranged in a line in the Y-axis direction.

Then, in step S15, the drawing-data generation unit 309 determines the micromirrors Ms to be set to the OFF state when exposing each square region based on the illuminance of the pattern image projected by each micromirror Ms so that the integrated illuminance of each square region becomes substantially equal (so that the integrated illuminance distribution becomes uniform in the Y-axis direction). The illuminance of the pattern image projected by each micromirror Ms may be obtained by using the measurement results by the measurement device 400 used to predict the integrated illuminance in each square region, or may be obtained by calculation based on the distance between the field stop FS and the DMD 10, the size of the DMD 10, and the like.

Then, in step S17, the drawing-data generation unit 309 generates drawing data based on the pattern for the display panel and the determination result of step S15. This makes it possible to generate drawing data that improves the uniformity of the integrated illuminance distribution in the Y-axis direction.

The drawing data storage unit 310 stores the drawing data generated by the drawing data generation unit 309. The drawing-data storage unit 310 sends the drawing data MD1 to MD27 for pattern exposure to the respective DMDs 10 of the 27 modules MU1 to MU27 illustrated in FIG. 2. The module MUn (n=1 to 27) selectively drives the micromirrors Ms of the DMD 10 based on the drawing data MDn to generate a pattern corresponding to the drawing data MDn, and projects and exposes the substrate P.

The drive control unit 304 creates control data CD1 to CD27 based on the measurement results of the interferometer IFX, and sends them to the modules MU1 to U27. The drive control unit 304 scans the XY stage 4A in the scanning direction (X-axis direction) at a predetermined speed based on the measurement results of the interferometer IFX.

During scanning exposure, the modules MU1 to MU27 control the driving of the micromirrors Ms of the DMD 10 based on the drawing data MD1 to MD27 and the control data CD1 to CD27 transmitted from the drive control unit 304.

The exposure control unit (sequencer) 306 controls the transmission of the drawing data MD1 to MD27 from the drawing data storage unit 310 to the modules MU1 to MU27 and the transmission of the control data CD1 to CD27 from the drive control unit 304 in synchronization with the scanning exposure (movement position) of the substrate P.

Other configurations are the same as those of the first embodiment, and thus the detailed description thereof will be omitted.

As described above in detail, according to the second embodiment, the exposure device EX is an exposure device that exposes the substrate P by irradiating the substrate P, which is moved in the scanning direction, with light from the DMD chip CHP, and the illumination unit ILU includes the optical integrators 108 on which the illumination light ILm is incident, and the field stop FS that is located on the optical path between the optical integrator 108 and the DMD 10 and forms an illuminance distribution on the DMD 10 in the scanning direction. This allows for a smaller variation in the integrated illuminance when one of the micromirrors Ms of the DMD 10 is set to the OFF state, than in a case where the illumination light ILm with an illuminance distribution that does not vary in the scanning direction is used. Therefore, the integrated illuminance can be corrected with higher resolution.

In the present embodiment, the exposure device EX is an exposure device that exposes the substrate P with pattern light generated according to the drawing data by the DMD 10 having a plurality of the micromirrors Ms two-dimensionally arranged, and includes the illumination unit ILU that irradiates the DMD 10 with the illumination light ILm, the projection unit PLU that projects an image of the pattern light generated by the DMD 10 onto the substrate P, and the exposure control device 300 that controls the ON state and the OFF state of the micromirrors Ms. The illumination light ILm has a predetermined illuminance distribution in which the illuminance varies according to the position in the X′-axis direction (also referred to as a direction corresponding to the scanning direction) close to the X-axis direction in which the substrate P is scanned, of the two axis directions (X′-axis direction and Y′-axis direction) that define the arrangement coordinate systems X′ and Y′ of the micromirrors Ms. The exposure control device 300 controls the ON state and the OFF state of the micromirror Ms based on the illuminance distribution. This allows for a smaller variation in the integrated illuminance when one of the micromirrors Ms of the DMD 10 is set to the OFF state, than in a case where the illumination light ILm that has an illuminance distribution where the illuminance does not vary in the X′-axis direction is used. Therefore, the integrated illuminance can be corrected with higher resolution.

In the present embodiment, the illumination unit ILU includes the optical integrator 108 that divides and superimposes the illumination light ILm, and the field stop FS that blocks a part of the illumination light ILm is provided on the optical path of the illumination light ILm between the optical integrator 108 and the DMD 10. The field stop FS blocks a part of the illumination light ILm along the Y′-axis direction. This makes it possible to form the illumination light ILm having a predetermined illuminance distribution in which the illuminance is different depending on the position in the X′-axis direction. The field stop FS may be disposed between the optical fiber bundle FBn and the optical integrator 108. In this case, for example, in the case where a fly eye lens including a plurality of small lenses is used for the optical integrator 108, the field stop FS is arranged on a conjugate plane of the optical integrator 108 with the spatial light modulator (for example, the DMD 10), and a part of the illumination light ILm incident on some of the small lenses can be thereby blocked. That is, the field stop FS is arranged only for some of the plurality of small lenses.

In addition, in the present embodiment, the field stop FS includes the first member 40a and the second member 40b, and the first member 40a and the second member 40b extend in the Y′-axis direction and are arranged at a predetermined interval in the X′-axis direction. This makes it possible to form the illumination light ILm having the top-hat illuminance distribution illustrated in FIG. 17B.

In addition, in the present embodiment, the lower surface of the field stop FS is substantially parallel to a neutral plane including the center point of each of the plurality of micromirrors Ms. This makes it possible to make the influence of telecentricity centrosymmetric.

In addition, in the present embodiment, the exposure device EX includes the substrate holder 4B on which the substrate P is placed, and the measurement device 400 that is provided on the substrate holder 4B and receives at least a part of the light of the image of the pattern light generated by the DMD 10 projected through the projection unit PLU. This enables measurement of the illuminance of the illumination light projected onto each light irradiation area 32, allowing prediction of the integrated illuminance at each position in the Y-axis direction.

In the present embodiment, the exposure control device 300 determines the micromirrors Ms to be set to the OFF state among the micromirrors Ms based on the measurement results of the illuminance by the measurement device 400. By using the measurement results of the illuminance by the measurement device 400, it is possible to determine the micromirror Ms that can cause the necessary change in the integrated illuminance.

In the above embodiment, the first member 40a and the second member 40b of the field stop FS are arranged so that the upper surface and the lower surface are parallel to the neutral surface of the DMD 10, but this does not intend to suggest any limitation.

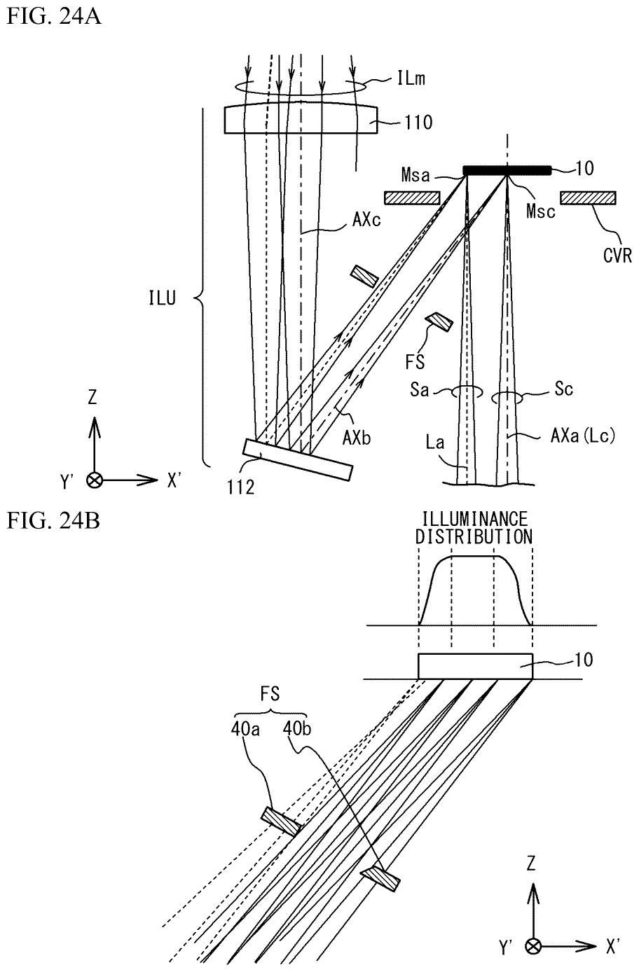

FIG. 24A illustrates another example of the arrangement of the first member 40a and the second member 40b of the field stop FS, and FIG. 24B illustrates an illuminance distribution obtained when the first member 40a and the second member 40b are arranged as illustrated in FIG. 24B. As illustrated in FIG. 24A, the first member 40a and the second member 40b may be arranged so that the lower surfaces thereof are perpendicular to the optical axis of the illumination light ILm.

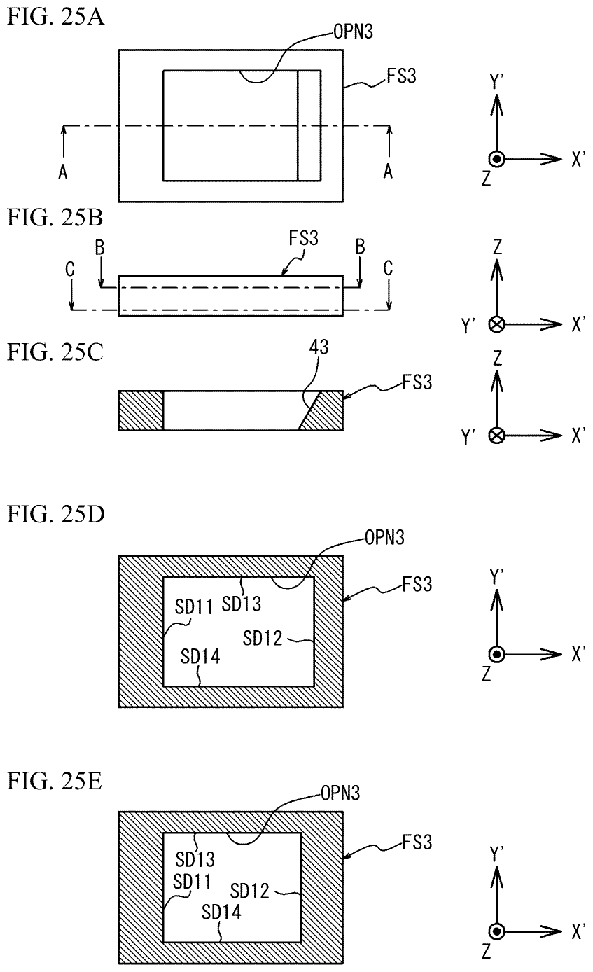

In the above embodiment, only one of the first member 40a and the second member 40b of the field stop FS may be disposed. A field stop having an aperture may also be used. FIG. 25A is a plan view illustrating an example of a field stop FS3 having an opening OPN3, FIG. 25B is a side view of the field stop FS3, FIG. 25C is a cross-sectional view taken along line A-A in FIG. 25A, FIG. 25D is a cross-sectional view taken along line B-B in FIG. 25B, and FIG. 25E is a cross-sectional view taken along line C-C in FIG. 25B.

As illustrated in FIG. 25A, the opening OPN3 is formed in the field stop FS3. The illumination light ILm passes through the opening OPN3 of the field stop FS3. The opening OPN3 has a non-circular shape. The shape of the opening OPN3 of the field stop FS3 may be, for example, a quadrangle (rectangle) or a rounded quadrangle (rounded rectangle). In this case, the opening OPN3 preferably has a shape in which two opposing sides SD11 and SD12 are parallel to the two opposing sides SD13 and SD14, respectively (angle θm between two sides is 0°) in a cross section orthogonal to the Z direction, or substantially parallel (0°<θm<10°, preferably 0°<θm<7°, more preferably 0°<θm<5°, and further preferably 0°<θm<1°).

As illustrated in FIG. 25C, a part of the inner wall surface 43 of the opening OPN3 is inclined with respect to the surface (X′Y′ plane) of the substrate SB. That is, as can be seen from FIG. 25B, FIG. 25C, and FIG. 25E, the opening OPN3 is larger on the side where the illumination light ILm is emitted than on the side where the illumination light ILm is incident. This allows a part of the illumination light ILm to be shielded, while enabling a part of the illumination light ILm to pass through the opening OPN3. The opening OPN3 may be a hole or a slit.

In the above embodiment, the integrated illuminance is corrected by reducing the exposure amount by setting the micromirror Ms to the OFF state, but this does not intend to suggest any limitation. For example, in a case where the micromirrors Ms in the outer peripheral region of the DMD 10 are set not to be used for the exposure processing (set to the OFF state), the integrated illuminance may be corrected by setting some of the micromirrors Ms in the outer peripheral region to the ON state to increase the exposure amount.

### (First Variation)

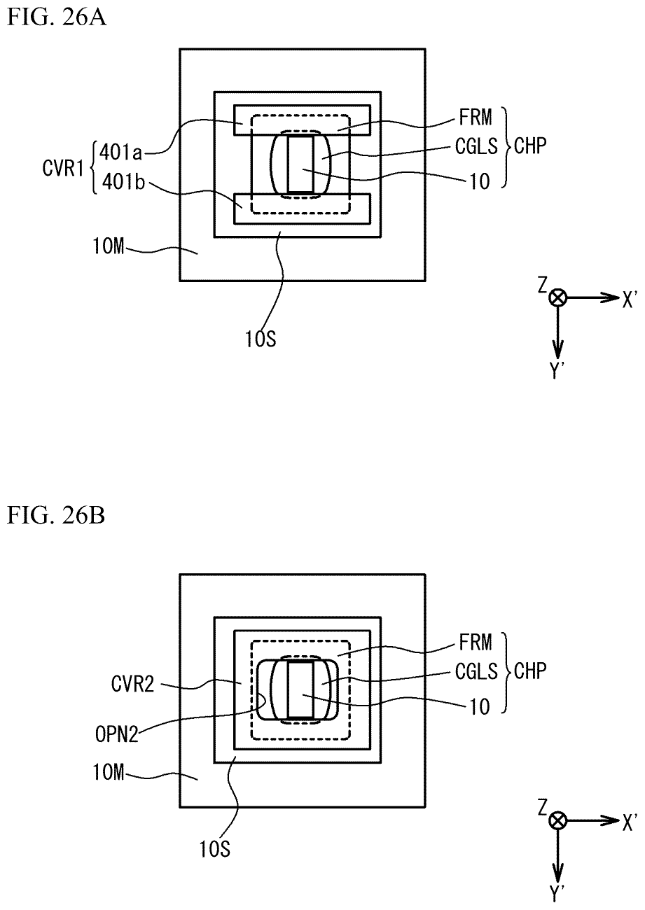

FIG. 26A illustrates a light-shielding cover CVR1 according to a first variation. The light-shielding cover CVR1 includes a first portion 401a and a second portion 401b that cover the part of the frame body FRM located outside the DMD 10 in the Y′-axis direction. In the above second embodiment, since the illumination light ILm is blocked by the field stop FS in the scanning direction (X-axis direction), light that generates scattered light (flare light) does not reach the DMD chip CHP. In this case, as illustrated in FIG. 26A, since it is sufficient to at least prevent the illumination light ILm from entering the portion of the frame body FRM located outside the DMD 10 in the Y′-axis direction, the generation of the scattered light (flare light) by the frame body FRM can be inhibited by arranging the first portion 401a and the second portion 401b extending in the X′-axis direction and covering the portion of the frame body FRM located outside the DMD 10 in the Y′-axis direction.

### (Second Variation)

FIG. 26B illustrates a light-shielding cover CVR2 according to a second variation. An opening OPN2 is formed in the light-shielding cover CVR2. The width of the opening OPN2 of the light-shielding cover CVR2 in the X′-axis direction is larger than the width of the opening OPN1 of the light-shielding cover CVR in the X′-axis direction. As described above, in the scanning direction (X-axis direction), the illumination light ILm is blocked by the field stop FS, and therefore, the light that generates the scattered light (flare light) does not reach the DMD chip CHP. Therefore, if the illumination light ILm can be at least prevented from entering the portion of the frame body FRM located outside the DMD 10 in the Y′-axis direction, the generation of the scattered light (flare light) by the frame body FRM can be inhibited. The opening OPN2 in the X′-axis direction may be widened as long as the illumination light ILm can be prevented from entering the portion of the frame body FRM located outside the DMD 10 in the Y′-axis direction.

### (Third Variation)

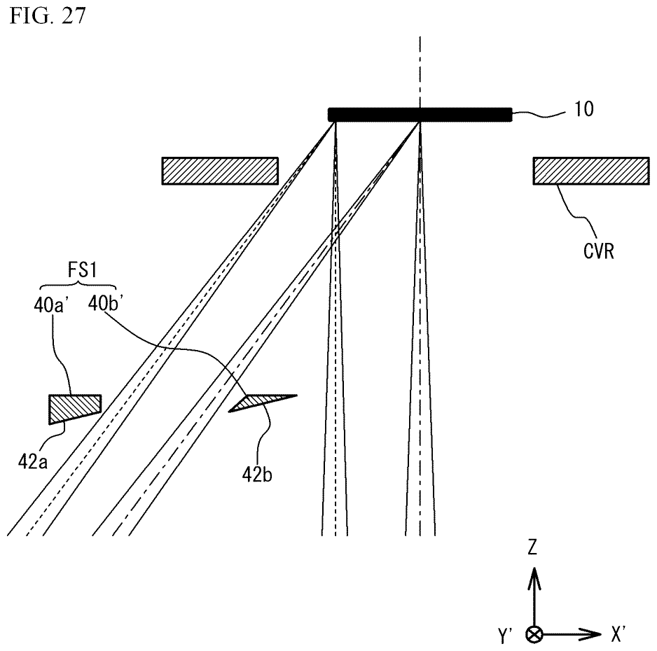

In the above second embodiment, the field stop FS is subjected to the low reflection treatment so that the reflectance to the illumination light ILm is 20% or less, preferably about 10% or less, but this does not intend to suggest any limitation. FIG. 27 illustrates a field stop FS1 according to a third variation.

The field stop FS1 includes a first member 40a′ and a second member 40b′. The field stop FS1 has a reflection surface that reflects the illumination light ILm. Specifically, in the field stop FS1, a lower surface 42a (surface on the −Z-side) of the first member 40a′ and a lower surface (surface on the −Z-side) 42b of the second member 40b′ are inclined with respect to the neutral plane of the DMD 10. Further, the lower surface 42a of the first member 40a′ and the lower surface 42b of the second member 40b′ are processed (for example, mirror polishing, metallic vapor deposition, mirror seal attachment, or the like) so that the reflectance to the illumination light ILm is 50% or greater, preferably about 75% or greater. This allows the lower surface 42a of the first member 40a′ and the lower surface 42b of the second member 40b′ to reflect the illumination light ILm, thereby inhibiting the temperature rise of the field stop FS1 caused by the illumination light ILm. The inclination angles of the lower surface 42a of the first member 40a′ and the lower surface 42b of the second member 40b′ are set so that the illumination light reflected by the lower surfaces 42a and 42b is absorbed by a light absorber (member other than the projection unit PLU). The illumination light reflected by the lower surfaces 42a and 42b may be absorbed by a light absorber that absorbs the illumination light reflected by the micromirrors Ms in the OFF state. That is, the light absorber that absorbs the discarded light from the DMD 10 and the light reflected by the lower surfaces 42a and 42b may be shared. This makes it possible to reduce the number of components as compared with a case where the light absorber 115 that absorbs the discarded light from the DMD 10 and a light absorber that absorbs the illumination light reflected by the lower surfaces 42a and 42b are separately provided.

Although not illustrated, the light-shielding covers CVR, CVR1, and CVR2 may also have a reflection surface that reflects the illumination light ILm. Specifically, the lower surfaces (the surfaces on the −Z side) of the light-shielding covers CVR, CVR1, and CVR2 may be inclined with respect to the neutral plane of the DMD 10 in the same manner as the field stop FS, and may be processed so that the reflectance to the illumination light ILm is 50% or greater, preferably 75% or greater. This can inhibit the temperature rise of the light-shielding covers CVR, CVR1, and CVR2 due to the illumination light ILm. The light-shielding covers CVR, CVR1, and CVR2 may also be configured so that the illumination light reflected by the lower surface is absorbed by the light absorber that absorbs the illumination light reflected by the micromirrors Ms in the OFF state.

### Third Embodiment

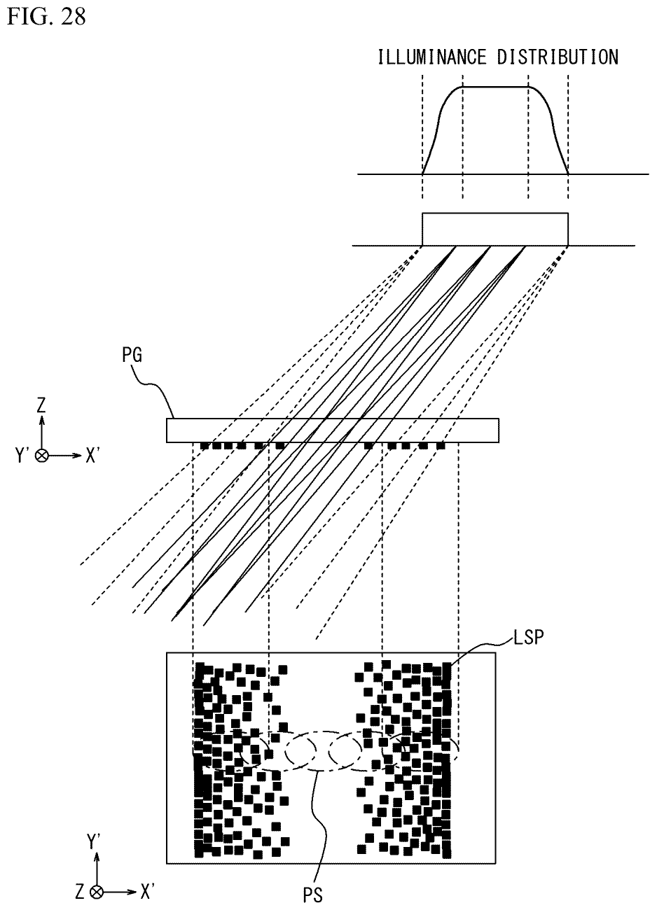

In the above second embodiment, a pattern glass PG on which a light shielding pattern LSP is formed may be used instead of the field stop FS. FIG. 28 is a diagram illustrating a third embodiment in which the pattern glass PG is disposed. The lower figure in FIG. 28 is a plan view of the pattern glass PG as viewed from the −Z direction.

As illustrated in FIG. 28, the pattern glass PG has the light shielding pattern LSP that shields a part of the illumination light ILm. The light shielding pattern LSP in FIG. 28 is a random dot pattern.

The transmittance of the illumination light ILm in the partial shapes PS located at both ends in the X′-axis direction among the partial shapes PS of the light beams of the illumination light ILm is reduced by the random dot pattern. As a result, as illustrated in the upper part of FIG. 28, an illuminance distribution in which the illuminance is different depending on the position in the X′-axis direction can be formed. The partial shape PS is a circle of diffraction (ellipse) of a light beam spread by NA at a position where the pattern glass PG is placed. The pattern glass PG uses the pattern density of the light shielding pattern LSP as a variable, and thus, it is easy to adjust the position at which the pattern glass PG is disposed and to control the illuminance distribution, compared to the field stop FS.

Other configurations are the same as those of the second embodiment, and thus the detailed description thereof will be omitted.

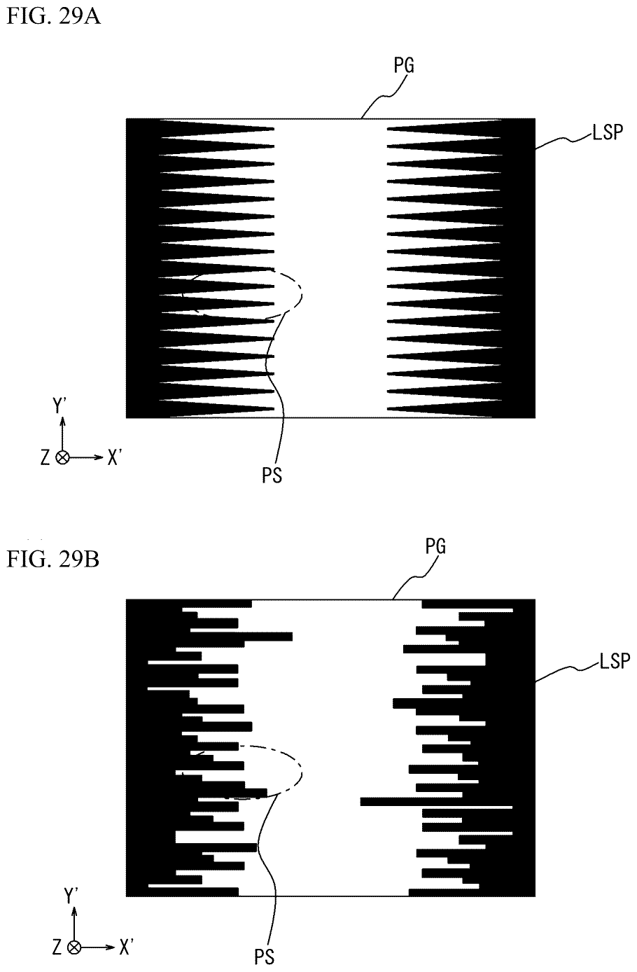

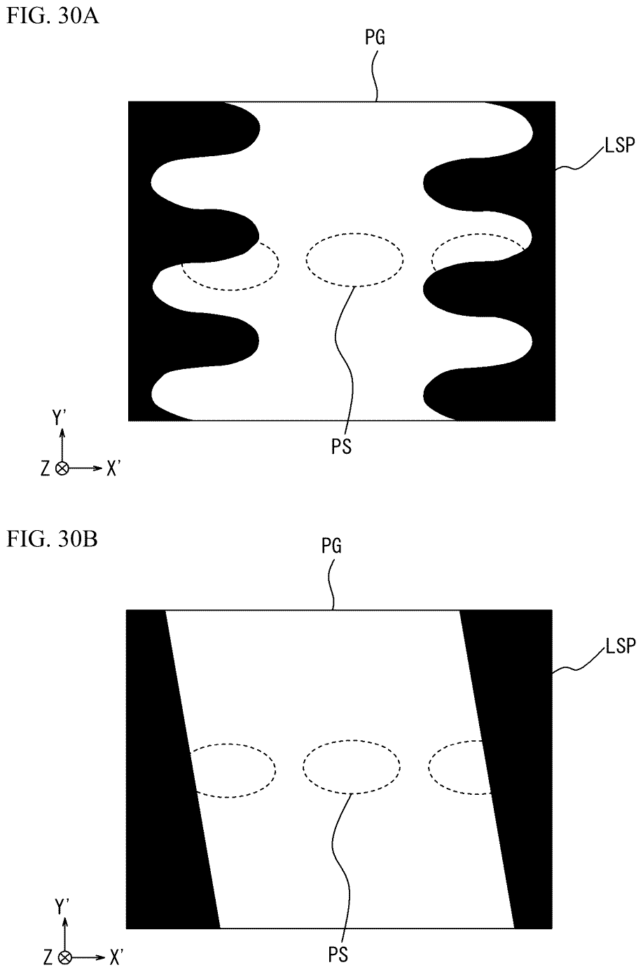

The light shielding pattern LSP is not limited to a random dot pattern. FIG. 29A to FIG. 30B illustrate other examples of the light-shielding pattern LSP. As illustrated in FIG. 29A, the light shielding pattern LSP may be a mountain-shaped pattern continuously arranged in the Y′-axis direction. As illustrated in FIG. 29A, the pattern density can be reduced from both ends of the pattern glass PG toward the center by the mountain-shaped pattern.

As illustrated in FIG. 29B, the light shielding pattern LSP may be a bar-shaped pattern. As illustrated in FIG. 30A, the light shielding pattern LSP may be a wave-shaped pattern. As illustrated in FIG. 30B, the light shielding pattern LSP may be a trapezoidal pattern. The shape of the field stop FS when viewed from the lower surface side may be the shape of the pattern in any one of FIG. 29A to FIG. 30B.

The size of the blur width of the pattern light may be controlled by moving the field stop FS or the pattern glass PG in the optical axis direction of the illumination light ILm, and the integrated illuminance may be corrected with high resolution when performing exposure on a layer requiring high illuminance uniformity, and the integrated illuminance may be corrected with low resolution when performing exposure on a layer having a large allowable range of required illuminance uniformity. In this case, when the integrated illuminance is corrected with high resolution, the region where the illuminance is 100% in the illuminance distribution of the illumination light ILm is narrow, and when the integrated illuminance is corrected with low resolution, the region where the illuminance is 100% in the illuminance distribution of the illumination light ILm is wide. Therefore, the integrated illuminance of each exposure target area in the case of correcting the integrated illuminance with high resolution is different from the integrated illuminance of each exposure target area in the case of correcting the integrated illuminance with low resolution. In this case, the relationship between the difference in illuminance distribution of the illumination light ILm and the integrated illuminance of each exposure target area is acquired in advance, and the integrated illuminance of each exposure target area is adjusted to a desired integrated illuminance.

In the above embodiments and variations, the illuminance distribution in which the illuminance of the illumination light ILm varies in the X′-axis direction is formed using the field stop FS or the pattern glass PG, but this does not intend to suggest any limitation. For example, the illumination light ILm having an illuminance distribution in which the illuminance varies in the X′-axis direction may be emitted from a single or a plurality of point light sources. In this case, the field stop FS and the pattern glass PG can be omitted.

In the above embodiments and variations, the field stop FS or the pattern glass PG is used, but this does not intend to suggest any limitation, and other light attenuation members can be used. As the light attenuation member, a filter or the like that attenuates a part of the illumination light ILm can be used. The light shielding member such as the field stop FS and the pattern glass PG is an example of a light attenuation member.

In the second and third embodiments, the case in which the illumination light ILm having the top-hat type illuminance distribution is formed has been described, but the illumination light ILm having the illuminance distribution in which the illuminance at both ends is high and the illuminance at the center is low may be formed.

In the above embodiments and variations, a heat sink may be disposed on the side opposite to the side on which the DMD 10 and the frame body FRM are mounted in the substrate SB of the DMD chip CHP. This makes it possible to extend the life of the DMD 10 (to inhibit a decrease in the reflectance of the DMD 10) and to stabilize the illuminance of the DMD 10.

In the above embodiments and variations, when the size of the illumination field area is larger than the size of the DMD 10, the illumination light ILm is prevented from entering the frame body FRM by using the light-shielding cover CVR, but this does not intend to suggest any limitation. For example, on the conjugate plane with the DMD 10, that is, on the incident plane of the MFE lens 108A, a diaphragm may be arranged for each MFE element using a fine pattern filter or the like to adjust the size of the illumination field area to a size such that the illumination light ILm does not enter the frame body FRM. This can inhibit the generation of scattered light (flare light) due to the illumination light ILm entering the frame body FRM.

Further, for example, an optical system may be added to the illumination unit ILU, a conjugate plane with the DMD 10 may be newly formed between the MFE lens 108A and the DMD 10, and the size of the illumination field region may be adjusted to a size such that the illumination light ILm is not incident on the frame body FRM on the new conjugate plane.

In the above embodiments and variations, the case where the illumination field area of the illumination light ILm emitted from the illumination unit ILU is a region obtained by adding the movable range of the DMD 10 to the dimensions of the DMD 10 in the X′-axis direction and the Y′-axis direction, and the size of the illumination field area is larger than the size of the DMD 10 has been described. Hereinafter, a case where the size of the illumination field area is substantially equal to or smaller than the size of the DMD 10 will be described.

[Case where the Size of the Illumination Field Area is Substantially the Same as the Size of the DMD 10]

First, a case where the size of the illumination field area is substantially equal to the size of the DMD 10 will be described.

In the case where the size of the illumination field area is substantially equal to the size of the DMD 10, when the DMD 10 is driven (moved) in the X′-axis direction, the Y′-axis direction, and the θz direction by the fine movement stage, the illumination light ILm may enter the frame body FRM. In addition, there is a possibility that a region that is not illuminated by the illumination light ILm is generated in the DMD 10. Therefore, when the size of the illumination field area is substantially the same as the size of the DMD 10, the illumination field area is shifted in the X-axis direction, the Y-axis direction, and the θz direction by providing a stage capable of driving the MFE lens 108A in the θx direction, the θy direction, and the θz direction, and the illumination field area is made to follow the DMD 10. This can inhibit the illumination light ILm from entering the frame body FRM or the region that is not illuminated by the illumination light ILm from being generated in the DMD 10 when the DMD10 is driven (moved) in the X′-axis direction, the Y′-axis direction, and the θz direction by the fine movement stage 10S.

The position of the illumination field area may be corrected by shifting the inclined mirror 112 in the Z-axis direction and rotating the inclined mirror 112 around the Z-axis, instead of driving the MFE lens 108A. Further, a double prism and a parallel flat glass may be inserted in the optical path between the MFE lens 108A and the DMD 10 so that the position of the illumination field area can be corrected.

[Case where the Size of the Illumination Field Area is Smaller Than the Size of the DMD 10]

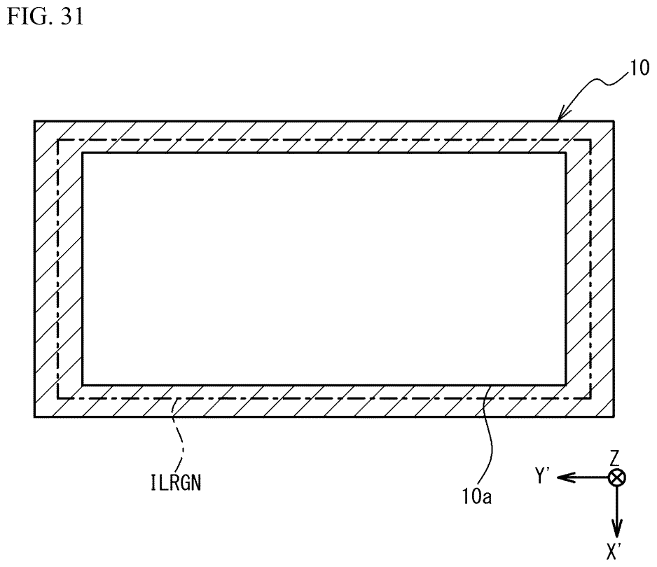

Next, a case where the size of the illumination field area is set to be smaller than the size of the DMD 10 will be described. FIG. 31 is a diagram for describing a case where the size of the illumination field area is set to be smaller than the size of the DMD 10. When the size of the illumination field area is set to be smaller than the size of the DMD 10, the illumination light ILm does not enter the frame body FRM of the DMD chip CHP, and thus the generation of scattered light (flare light) is inhibited.

When the size of the illumination field area is set to be smaller than the size of the DMD 10, the micromirrors Ms provided on the outer periphery of the DMD 10 indicated by hatching in FIG. 31 among the micromirrors Ms provided in the DMD 10 are not used for pattern generation (are always turned off). Therefore, the region excluding the outer peripheral portion of the DMD 10 is the pattern generation region 10a. In this case, the size of the illumination field area is set so that the pattern generated in the pattern generation region 10a is illuminated with the illumination light ILm. Specifically, a region obtained by adding the movable range of the DMD 10 to the size of the pattern generation area 10a is set as the illumination field area ILRGN (indicated by a one dot chain line). Therefore, the size of the illumination field region ILRGN is larger than the size of the pattern generation region 10a and smaller than the size of the DMD 10. By setting the size of the illumination field region in this manner, it is possible to expose a pattern on the substrate P while inhibiting the generation of scattered light (flare light).

The light-shielding cover CVR may be provided in both cases where the size of the illumination field region is substantially the same as the size of the DMD 10 and where the size of the illumination field region is smaller than the size of the DMD 10.

The above-described embodiments and variations are preferred examples of the present invention. However, this does not intend to suggest any limitation, and various modifications can be made without departing from the scope of the present invention. The embodiments and the variations can be combined with each other as appropriate.

What is claimed is:

1. A spatial light modulation unit comprising:
a spatial light modulator including:
a substrate;
a plurality of mirrors arranged over a surface of the substrate in a plan view; and
a frame body over the substrate, the frame body surrounding the plurality of mirrors in the plan view; and
a cover that is located over the frame body, is attached to the spatial light modulator so that a relative positional relationship with the spatial light modulator is fixed, and restricts incidence of light on the frame body,
wherein a first surface of the cover faces the frame body,
wherein an opening of the cover extends from a side of the first surface to a side of a second surface, which is opposite to the side of the first surface, of the cover, and
wherein each of the plurality of mirrors is able to be brought into a plurality of states.

2. The spatial light modulation unit according to claim 1, wherein, in a direction perpendicular to the surface, the opening overlaps the frame body and a gap between adjacent mirrors of the plurality of mirrors.

3. The spatial light modulation unit according to claim 1, wherein an area of a cross-section on the side of the first surface in the opening is smaller than an area of a cross-section on the side of the second surface in the opening, and each of the cross-section on the side of the first surface and the cross-section on the side of the second surface is parallel to the surface.

4. The spatial light modulation unit according to claim 1, wherein a distance between the first surface and a plane including respective centers of the plurality of mirrors is equal to or greater than a distance between the first surface and the frame body.

5. An exposure device comprising:
the spatial light modulation unit according to claim 1; and
a projection unit that projects light from the spatial light modulator onto an object,
wherein tan θin<Lin/Hin is satisfied,
wherein light from a mirror in an ON state of the plurality of mirrors enters the projection unit,
wherein θin is twice an inclination angle of a reflection surface of the mirror in the ON state of the plurality of mirrors from a plane including respective centers of the plurality of mirrors,
wherein Lin is a distance between an edge of the opening and a mirror closest to the edge among the plurality of mirrors in the plan view, and
wherein Hin is a distance between the first surface and a plane that includes respective points closest to the substrate in respective reflection surfaces of mirrors in the ON state of the plurality of mirrors.

6. An exposure device comprising:
the spatial light modulation unit according to claim 1; and
a projection unit that projects light from the spatial light modulator onto an object,
wherein a distance between the first surface and a plane including respective centers of the plurality of mirrors is H,
wherein a distance between an edge of the opening and a mirror closest to the edge of the opening among the plurality of mirrors in a plan view is L,
wherein a numerical aperture of the projection unit is NA,
wherein a refractive index on an optical path from the spatial light modulator to the projection unit is n, and an optical magnification is β, and
wherein tan θ_{NA}<L/H is satisfied, where θ_{NA}=sin⁻¹(NA×β/n).

7. An exposure device comprising:
the spatial light modulation unit according to claim 1;
an illumination unit that illuminates the spatial light modulator with illumination light; and
a stage on which the spatial light modulator is mounted and that is movable in a first direction and a second direction intersecting with the first direction, the first direction and the second direction being parallel to the surface,
wherein an illumination region of the illumination unit is set so that the illumination unit illuminates the plurality of mirrors and a vicinity of the plurality of mirrors,
wherein the plurality of mirrors are irradiated by the illumination region regardless of a position of the stage within a movable range in the first direction of the stage, and
wherein the plurality of mirrors are irradiated by the illumination region regardless of a position of the stage within a movable range in the second direction of the stage.

8. The exposure device according to claim 7,
wherein the exposure device irradiates an object moved in a scanning direction with light from the spatial light modulator so as to expose the object, and
wherein the illumination unit includes:
an optical integrator; and
a light attenuation member that is located on an optical path between the optical integrator and the spatial light modulator and forms an illuminance distribution on the spatial light modulator in the scanning direction.

9. The exposure device according to claim 8, wherein a size of an opening of the light attenuation member is larger on a side where the illumination light is emitted than on a side where the illumination light enters.

10. The exposure device according to claim 8,
wherein the illuminance distribution includes a region with illuminance greater than 0% and less than 50% of maximum illuminance in the illuminance distribution,
wherein an opening of the light attenuation member has a non-circular shape, and
wherein the illumination light passes through the opening of the light attenuation member.

11. The exposure device according to claim 8,
wherein an inner wall surface of an opening of the light attenuation member is inclined with respect to the surface.

12. The exposure device according to claim 8, wherein the light attenuation member is attached to the spatial light modulator so that a relative positional relationship with the spatial light modulator is fixed.

13. The exposure device according to claim 8, further comprising:
a projection unit that projects light from the spatial light modulator onto the object,
wherein the light attenuation member includes a reflection surface that reflects the illumination light, and
wherein the exposure device further includes a light absorbing member on which light from the reflection surface of the light attenuation member and light from a mirror in an OFF state of the plurality of mirrors are incident.

14. The spatial light modulation unit according to claim 1, wherein a reflectance of the frame body with respect to light with a peak in a wavelength range of 10 nm or more to 410 nm or less is smaller than a reflectance of a mirror of the plurality of mirrors with respect to the light.

15. The spatial light modulation unit according to claim 1, further comprising:
a heat sink disposed on a side opposite to a side on which the plurality of mirrors and the frame body are mounted, in the substrate, and
wherein a reflectance of the cover with respect to light having a peak wavelength within a range of wavelengths from 10 nm to 410 nm is less than a reflectance of a mirror of the plurality of mirrors with respect to the light.

16. An exposure device comprising:
a spatial light modulator including a plurality of elements arranged on a surface in a plan view and a frame body surrounding the plurality of elements in the plan view;
an illumination unit that illuminates the spatial light modulator with illumination light;
a light shielding member that is attached to the spatial light modulator so that a relative positional relationship with the spatial light modulator is fixed and blocks the illumination light from entering the frame body;
a projection unit that projects light from the plurality of elements onto an object; and
a stage on which the spatial light modulator is mounted and that is movable in a plane intersecting an optical axis of the projection unit,
wherein an illumination region of the illumination unit is set so that the plurality of elements and a region surrounding the plurality of elements in the plan view are illuminated with the illumination light,
wherein the plurality of elements are irradiated by the illumination region regardless of a position of the stage within a movable range in a first direction in the plane, and
wherein the plurality of elements are irradiated by the illumination region regardless of a position of the stage within a movable range in a second direction, which intersects with the first direction in the plane.

17. The exposure device according to claim 16,
wherein a first surface of the light shielding member faces the frame body,
wherein an opening of the light shielding member extends from a side of the first surface to a side of a second surface, which is opposite to the side of the first surface, of the light shielding member,
wherein an area of a cross-section on the side of the first surface in the opening is smaller than an area of a cross-section on the side of the second surface in the opening, and each of the cross-section on the side of the first surface and the cross-section on the side of the second surface is parallel to the surface.

18. The exposure device according to claim 17,
wherein the light shielding member includes a light-shielding cover in which a substantially quadrangular opening through which the illumination light passes is formed.

19. The exposure device according to claim 18, wherein a size of the opening of the light-shielding cover, a position of the opening of the light-shielding cover, and a distance between a plane including respective centers of the plurality of elements and the first surface in a third direction perpendicular to the plane are set so as not to prevent the illumination light from entering the plurality of elements and not to block light reflected by an element in an OFF state of the plurality of elements.

20. The exposure device according to claim 19,
wherein the illumination light is obliquely incident on the plurality of elements,
wherein the opening of the light-shielding cover includes two sides facing each other in a fourth direction substantially parallel to a scanning direction and extending in a fifth direction substantially perpendicular to the fourth direction in a horizontal plane, and
wherein a first distance in the fourth direction between the plurality of elements and one side, which is on an incident side of the illumination light, of the two sides of the opening of the light-shielding cover is longer than a second distance in the fourth direction between the plurality of elements and another side of the two sides of the opening of the light-shielding cover.

21. The exposure device according to claim 20,
wherein tan θin<Lin/Hin is satisfied, where Lin represents the first distance, Hin represents a distance in the third direction between the plane and a first portion, which includes the one side, of the light-shielding cover, and θin represents an incident angle at which the illumination light is incident on the plurality of elements.

22. The exposure device according to claim 16,
wherein the light shielding member includes:
a light attenuation member that attenuates at least a part of light with which the spatial light modulator is irradiated and forms an illuminance distribution along a third direction corresponding to a scanning direction through the projection unit in at least a part of an illumination region on the plurality of elements; and
a light-shielding cover that at least blocks the illumination light from entering a portion of the frame body, the portion being located outside the plurality of elements in a fifth direction perpendicular to a fourth direction substantially parallel to the scanning direction in a horizontal plane.

23. The exposure device according to claim 22,
wherein a reflectance of a first surface, which is on a side opposite to the spatial light modulator, of the light attenuation member with respect to the illumination light is 50% or greater, and
wherein the first surface is inclined with respect to a plane including respective centers of the plurality of elements.

24. The exposure device according to claim 18,
wherein a reflectance of the second surface with respect to the illumination light is 20% or less, and
wherein a surface opposite from the spatial light modulator of the light-shielding cover has a reflectance with respect to the illumination light of 50% or greater, and is inclined with respect to a plane including respective centers of the plurality of elements.
